(19) United States
(12) Patent Application Publication
(10) Pub. No.: US 2011/0068332 A1
(43) Pub. Date: Mar. 24, 2011

(54) Hybrid Dielectric Material for Thin Film Transistors

(75) Inventors: Lin HAN, Princeton, NJ (US); Prashant MANDLIK, Lawrenceville, NJ (US); Sigurd WAGNER, Princeton, NJ (US)

(73) Assignee: THE TRUSTEES OF PRINCETON UNIVERSITY, PRINCETON, NJ (US)

(21) Appl. No.: 12/943,398

(22) Filed: Nov. 10, 2010

Related U.S. Application Data
(63) Continuation-in-part of application No. PCT/US2009/052233, filed on Jul. 30, 2009.
(60) Provisional application No. 61/086,047, filed on Aug. 4, 2008.
(60) Provisional application No. 61/281,536, filed on Nov. 19, 2009.

(51) Int. Cl. H01L 51/50; H01L 33/08

(52) U.S. Cl. 257/40; 257/59; 257/E33.053; 257/E51.018

(57) ABSTRACT

Thin-film transistors are made using a hybrid silica-silicone material as an insulating material. The hybrid silica-silicone material may be deposited by plasma-enhanced chemical vapor deposition from siloxanes and oxygen. These hybrid materials may be employed as the gate dielectric, as a subbing layer, and/or as a back channel passivating layer. The transistors may be made in any conventional TFT geometry.

### RELATED APPLICATIONS

This application is a continuation-in-part of International patent application Ser. No. PCT/US2009/052233 (filed on 30 Jul. 2009), which claims priority to U.S. Provisional Application No. 61/086,047 (filed on 4 Aug. 2008). This application also claims the benefit of U.S. Provisional Application No. 61/281,536 (filed on 19 Nov. 2009). The contents of all these applications are incorporated herein by reference in their entirety.

### JOINT RESEARCH AGREEMENT

The claimed inventions were made by, on behalf of, and/or in connection with one or more of the following parties to a joint university-corporation research agreement: Princeton University, The University of Southern California, and the Universal Display Corporation. The agreement was in effect on or before the date the claimed inventions were made, and the claimed inventions were made as a result of activities undertaken within the scope of the agreement.

### TECHNICAL FIELD

The present invention relates to thin film transistors.

### BACKGROUND

A thin film transistor (TFT) is a particular type of field effect transistor, made by depositing thin films of a semiconductor active layer, a dielectric layer, and metallic contacts over a supporting substrate. The primary application of TFTs is in liquid crystal displays, and for this reason the most common substrate is glass. This differs from conventional transistors used in electronics, where the semiconductor material, typically a silicon wafer, is the substrate. Transparent TFTs (TTFTs) are particularly desirable for displays that rely on pixel-by-pixel modulation of light emitted by a backlight.

TFTs can be made using a wide variety of semiconductor materials. A common material is silicon. The characteristics of a silicon-based TFT depend on the silicon crystalline state. The semiconductor layer can be amorphous silicon or microcrystalline silicon, or it can be annealed into polysilicon. Other materials which have been used as semiconductors in TFTs include compound semiconductors such as cadmium selenium (CdSe) and metal oxides such as zinc oxide. TFTs have also been made using organic materials (Organic TFTs or OTFTs).

The glass substrates used in typical liquid crystal displays cannot withstand the high temperatures characteristic of polysilicon transistor fabrication (or will require many hours of processing time at temperatures that are suitable for glass substrates). For this reason, amorphous silicon, because of its low dark conductivity and relatively easy fabrication on large area substrates at moderate temperatures, is a very effective active layer material for high resolution large area displays. The most common TFTs in use today are based on hydrogenated amorphous silicon (“a—Si:H”) as the semiconductor active layer.

Chemical vapor deposition (CVD), plasma-enhanced chemical vapor deposition (PE-CVD), and physical vapor deposition methods such as sputtering are most commonly employed for the deposition of the silicon, insulating, and conducting layers that constitute a TFT. Solution-processed transparent TFTs based on chemical precipitation of zinc oxide and silicon dioxide have also been reported.

In a transistor, there are typically three electrodes, serving as gate, source, and drain. The gate electrode supplies the controlling voltage to the transistor, and the semiconductor channel of the transistor conducts current from the source to the drain in response to the gate voltage. The gate insulator, or gate dielectric, of a TFT electrically insulates the gate from the semiconductor channel. Superior performance in a TFT requires a high channel conductance, fast “on” and “off” responses to the applied gate voltage, a very rapid increase and decrease in the source-to-drain current as the gate voltage rises and falls past a threshold switching value, minimal current leakage from the source to the drain in the absence of an applied gate voltage and negligible current leakage from the channel to the gate. These operating characteristics should be stable, and should not change or drift after a long period of applied gate voltage.

The gate dielectric material plays a critical role in determining the performance of a TFT. In general, a thinner gate dielectric layer leads to a greater voltage gradient across the gate dielectric layer, and this in turn leads to the more rapid generation of more charge carriers in the semiconductor, and permits a reduction in driving voltage. The properties of the gate dielectric material set a limit on how thin this layer can be. The material must not break down and conduct current under the influence of the voltage gradient, it must bind to the semiconductor channel material without leaving too many dangling bonds (“interface states”), it must be tough enough to withstand thermal cycling without fracturing or separating from the various materials it is bonded to (typically, the substrate, gate, and dielectric layers), and it must exhibit stable properties under extended application of a gating voltage. Furthermore, in order to be commercially feasible, the material should be easily laid down and patterned using existing microfabrication technology. It should be capable of producing extremely thin layers with extraordinary uniformity, because large displays can contain millions of pixels, and the acceptable defect rate among the millions of TFTs in each such display is generally close to zero. Among the most suitable materials for TFTs are silicon oxide (SiOₓ) and silicon nitride (SiNₓ). Although silicon nitride is generally considered to be the superior gate dielectric for a—Si:H TFTs, there are disadvantages to SiNₓ as an gate dielectric: it is brittle, requires a thickness of at least 300 nm, and has relatively low transparency. Prolonged application of a gating bias can cause charge trapping at the interface with the a—Si:H, which leads to a shift in the threshold voltage of the TFT. There remains a need for more stable, flexible and transparent gate dielectric materials, especially for use on flexible substrates.

In addition to the interface with the gate dielectric, the interface on the other side of the a—Si:H channel, the so-called “back-channel”, also influences the performance of the transistor. In particular, the etching and subsequent application of a dielectric “passivation layer” to the a—Si:H back channel can lower the density of surface states, and control surface leakage and photoleakage currents. In a back channel etched (BCE) a—Si:H TFT, a passivation layer is necessary to protect the back channel from damage and contamination during subsequent processing. For conventional BCE TFT devices, PECVD-deposited silicon nitride (SiNₓ) is commonly used as a passivation layer. However, there remains a need for lower-dielectric, lower-stress, and higher-transmittance dielectric materials for back-channel passivation in TFTs.

Liquid crystal display panels are increasingly popular for computer display screens and flat-panel television sets. The market for these commercial products continuously demands larger-sized displays, higher resolutions, and higher color image rendering capabilities. There is a need for thin film transistors, suitable for use as switching devices in active-matrix displays, that are economical to manufacture, with low defect rates and improved electrical characteristics, such as high field effect mobility, reliability against high frequency, and low leakage current.

Organic high-emitting displays are a new technology for flat-panel displays. Commercial production of OLED displays is accelerating rapidly, because of their several advantages over liquid-crystal displays. Organic light-emitting displays rely on thin-film transistors that continuously provide direct current, and as a result there is a need for transistors that are particularly stable in long-term use.

Volatile silanes and silicones are commonly used as silicon source gases for plasma enhanced chemical vapor deposition (PE-CVD) growth of carbon-containing silicon oxide films, sometimes referred to as organosilicate glass (OSG). OSG is commonly used for insulating layers (low-k dielectrics) between passive conductive elements, and as the underlying insulator in damascene processes. At high oxygen/silicone ratios, the resulting films are harder and more silica-like than at low oxygen/silicone ratios, and such films have been used as hard protective coatings on polymers and metals.

### SUMMARY

The present invention provides transistors having one or more insulating layers made from a hybrid silica-silicone material, also known in the art as an organosilicate glass (OSG). The OSG layers of the invention have physical and electrical properties that make them particularly suited for use in thin-film field-effect transistors. In certain embodiments, the invention provides gate dielectric layers, back channel passivation layers, and/or substrate passivation layers, which consist essentially of the hybrid silica-silicone material. The hybrid material is preferably formed by plasma-enhanced chemical vapor deposition from a gas mixture comprising a volatile silicone precursor and an oxidant. The oxidant may be any oxidant gas known in the art, including but not limited to oxygen gas, hydrogen peroxide, ozone, and nitrous oxide. Oxygen gas is preferred.

The gas mixture may optionally include inert gases such as argon, and reactive gases that contribute atoms to the gate insulator layer. Examples include, but are not limited to, reactive gases that contribute nitrogen atoms to the organosilicate glass. Suitable nitrogen donors include, but are not limited to, organic silazanes and silylated nitrogen compounds, ammonia, and nitrogen gas.

In one aspect, the invention provides a process for depositing a layer of organosilicate glass, and for the use of this process in depositing gate dielectric, back channel passivation, and substrate passivation layers in the manufacture of TFTs, other insulated gate field effect transistors, and related devices.

In certain embodiments, the present invention provides an electronic device comprising a field-effect transistor, the field-effect transistor comprising: a semiconductor active layer comprising a semiconductor material; a source electrode and a drain electrode; a gate electrode; and an insulating material disposed between the gate electrode and the semiconductor active layer, the insulating material consisting essentially of an organosilicate glass.

In some cases, the semiconductor material is an organic semiconductor. In some cases, the semiconductor material is selected from amorphous silicon, nanocrystalline silicon, microcrystalline silicon, polycrystalline silicon, zinc oxide, zinc tin oxide, or zinc gallium oxide. In some cases, the device further comprises a back channel passivation layer consisting essentially of a hybrid silica-silicone material, the back channel passivation layer being in physical contact with the semiconductor active layer. In some cases, the back channel passivation layer consists of a hybrid silica-silicone material. In some cases, the hybrid silica-silicone material is deposited by plasma-enhanced chemical vapor deposition from a gas mixture comprising one or more volatile silicone precursors and oxygen. In some cases, the gas mixture further comprises one or more volatile sources of nitrogen.

In some cases, the device further comprises a flexible substrate, wherein the field-effect transistor is mounted over the flexible substrate. In some cases, the device further comprises a subbing or passivation layer disposed between the substrate and the field-effect transistor. In some cases, the subbing or passivation layer consists essentially of a hybrid silica-silicone material. In some cases, the subbing or passivation layer consists of a hybrid silica-silicone material. In some cases, the insulating material forms a gate insulator layer having a thickness of less than 300 nm. In some cases, the gate insulator layer has a thickness of less than 250 nm. In some cases, the transistor has an effective electron field-effect mobility of greater than 1.5 cm²/V·s in the linear region, an on/off current ratio of greater than 1×10⁶, a threshold voltage of less than 4.0 V, and a subthreshold slope of less than 500 mV/dec.

In certain embodiments, the present invention provides a method of making a field-effect transistor, comprising the steps of: providing a substrate; forming a gate insulator layer over the substrate by steps comprising: (a) placing the substrate in a deposition chamber; (b) introducing into the chamber a source gas comprising a volatile silicone precursor and at least one oxidant gas selected from the group consisting of oxygen, ozone, hydrogen peroxide, and nitrous oxide; and (c) applying radio frequency, microwave frequency, or DC power to the chamber.

The electronic device may be the field-effect transistor itself (e.g., mounted on a substrate) or any device that uses a field-effect transistor, including organic light emitting devices and display screens (such as liquid crystal displays used in flat panel televisions and computer monitors). Where one component is in “electrical connection” or “electrically connected” with another component, it means that the components are arranged such that electrical current may flow from one component to the other. There may or may not be other components (e.g., conducting or semiconducting materials) physically between the two components.

Where a first component is described as being “over” a second component, at least a portion of the first component is disposed further away from substrate. This includes the possibility that the first and second components are in physical contact with each other (e.g., the first component is disposed on the second component) or there may be other components between the first and second components. For example, in a top-gate architecture for a TFT, the gate electrode may be described as being disposed “over” a substrate, even though there are various components in between.

### BRIEF DESCRIPTION OF THE DRAWINGS

FIG. 1 is a schematic cross-sectional view of an a—Si:H TFT according to an embodiment of the invention, with a 250 nm hybrid dielectric gate insulating layer deposited at nominal room temperature.

FIG. 2 shows the output characteristics of the TFT of FIG. 1.

FIG. 3 shows the output characteristics in the linear regime of the TFT of FIG. 1.

FIG. 4 shows the transfer characteristics and gate leakage current of the TFT of FIG. 1.

FIG. 5 shows the threshold-voltage shift versus gate-bias field for the TFT of FIG. 1 with the hybrid gate dielectric, and of TFTs with a conventional SiNₓ gate dielectric fabricated at 150° C., 250° C., 300° C., and 350° C., on glass or plastic substrates.

FIG. 6 is a schematic cross-sectional view of an a—Si:H TFT according to an embodiment of the invention, with a 100-nm hybrid dielectric gate insulator deposited at a temperature of about 300° C.

FIG. 7 shows the output characteristics of the TFT of FIG. 6, before and after gate-bias stressing.

FIG. 8 shows the transfer characteristics and gate leakage current of the TFT of FIG. 6, before and after gate-bias stressing.

FIG. 9 shows the threshold-voltage shift versus gate-bias field for the TFT of FIG. 6, and of TFTs with a conventional SiNₓ gate dielectric fabricated at 300° C. and 350° C.

FIG. 10 is a schematic cross-sectional view of an a—Si:H TFT according to an embodiment of the invention, with a 100-nm hybrid dielectric gate insulator, a 150-nm a—Si:H channel, and 150-nm hybrid dielectric passivation layer between the channel and the source/drain.

FIG. 11 shows the output characteristics of the TFT of FIG. 10.

FIG. 12 shows the transfer characteristics and gate leakage current of the TFT of FIG. 10.

FIG. 13 shows the breakdown field of a hybrid dielectric layer as a function of the molar ratio of hexamethydisiloxane to oxygen used to deposit the layer.

FIG. 14 shows a flexible TFT having a hybrid OSG back channel passivation layer.

FIG. 15 shows an example of how an inverted-staggered TFT on a glass substrate may be made.

FIG. 16 shows an example of how an inverted-staggered TFT on a flexible polyimide substrate may be made.

FIG. 17 shows an example of how a top-gate staggered TFT on glass may be made.

FIGS. 18A and 18B show schematic cross-section views of amorphous Si:H TFTs having an inverted staggered geometry. In the TFT of FIG. 18A, the gate insulator layer is made of a hybrid silica-silicone material. The TFT of FIG. 18B has a conventional gate insulator layer made of SiNₓ. The inscriptions show the layer thickness, material composition, and process deposition temperature.

FIG. 19 shows a top view micrograph of a representative hybrid material TFT with the inscriptions indicating the channel dimensions.

FIGS. 20A and 20B show plots of the transfer characteristics obtained for hybrid material TFTs before and after bending. FIG. 20A shows the results from tensile straining FIG. 20B shows the results from compressing straining.

FIGS. 21A and 21B show a plot of various electrical characteristics of the hybrid material TFTs measured after the strain (abscissa) was applied.

FIGS. 22A and 22B show a handheld electronic device having a flexible display screen that is rolled on a spindle. FIG. 22A shows a partial, side view of the electronic device. FIG. 22B shows a top view of the electronic device.

FIGS. 23A and 23B show the handheld electronic device of FIG. 22 with the flexible display screen being unfurled off the spindle. FIG. 23A shows a partial, side view of the electronic device. FIG. 23B shows a top view of the electronic device.

### DETAILED DESCRIPTION

The invention provides a field-effect transistor comprising one or more insulating layers, which consist essentially of an organosilicate glass. In some embodiments, one or more of the insulating layers consist entirely of the organosilicate glass. Preferably, the transistor comprises a gate insulator material disposed between a gate electrode and a semiconductor active layer, wherein the gate insulator material consists essentially (or entirely) of an organosilicate glass. The transistors of the invention may optionally comprise a back channel passivation layer, and/or a subbing layer, consisting essentially (or entirely) of an organosilicate glass.

The organosilicate glass preferably comprises from about 70% to about 95% silicon dioxide and about 30% to about 5% siloxane polymer. The organosilicate glass is most conveniently deposited by plasma-enhanced chemical vapor deposition from a gas mixture comprising one or more volatile silicone precursors and an oxidant gas such as oxygen, in which the volume flow ratio of oxidant gas to volatile silicone precursor is at least 25:1. The volume flow percentage, measured in standard cubic centimeters per minute, of volatile silicone precursor in oxygen is preferably between 0.1% and 10%, more preferably between 0.5% and 8%, still more preferably between 1% and 6%, and is most preferably between 2% and 5%.

The transistors of the invention may be fabricated upon a rigid or a flexible substrate, which may optionally include one or more subbing layers (to improve adhesion) or passivation layers disposed between the substrate and the transistor. The passivation layer preferably consists essentially (or entirely) of an organosilicate glass, and may optionally be laid down over an adhesion-improving (subbing) layer of SiNx.

The invention also provides a method of forming an “inverted staggered” field-effect transistor having an organosilicate glass gate insulator layer, comprising the steps of: (a) depositing a gate electrode on a substrate; (b) placing the substrate with the gate electrode in a PE-CVD chamber; (c) introducing into the chamber a source gas comprising a volatile silicone precursor and at least one oxidant gas selected from the group consisting of oxygen, ozone, hydrogen peroxide, and nitrous oxide; and (d) applying radio frequency, microwave frequency, or DC power to the chamber; so that a layer of organosilicate glass is deposited on the gate electrode and substrate.

The method further comprises the step of depositing source and drain layers, preferably accomplished by depositing a layer of amorphous hydrogenated silicon, a layer of doped (donor or acceptor) amorphous hydrogenated silicon, and a layer of crystalline silicon (e.g., nanocrystalline, microcrystalline, or polycrystalline silicon). The method further comprises depositing a conductive layer to serve as source and drain electrodes.

The substrate may be any substrate known in the art upon which field effect transistors can be made, for example, a glass, a polymer foil or a metal foil. Lithography, patterning and etching of the various layers, so as to arrive at a functional transistor, are carried out as is well-known in the art.

In an alternative embodiment, the invention also provides a method of forming a “top gate” field-effect transistor having an organosilicate glass gate insulator layer, comprising the steps of: (a): depositing a source/drain conductor layer on a substrate; (b) depositing a layer of doped amorphous hydrogenated silicon on the source/drain conductor layer; (c) patterning the doped amorphous hydrogenated silicon layer and source/drain conductor layer, so as to form separate source and drain electrodes; (d) depositing a layer of amorphous hydrogenated silicon; (e) mounting the substrate with electrodes and silicon layer in a PE-CVD chamber; (f) introducing into the chamber a source gas comprising a volatile silicone precursor and at least one oxidant gas selected from the group consisting of oxygen, ozone, hydrogen peroxide, and nitrous oxide; and (g) applying radio frequency, microwave frequency, or DC power to the chamber; so that a layer of organosilicate glass is deposited on the amorphous hydrogenated silicon layer.

Typically, the above method will further comprise the steps of depositing a gate conductor layer on the amorphous hydrogenated silicon, and patterning the gate conductor so as to form a gate electrode, and the step of patterning the organosilicate glass, amorphous hydrogenated silicon, and doped amorphous hydrogenated silicon layers, so as to expose the source and drain electrodes.

In yet another embodiment, the invention provides a method of forming a transistor having an organosilicate glass gate insulator, comprising the steps of (a) preparing on a substrate a film of silicon, wherein the silicon is selected from the group consisting of amorphous silicon, nanocrystalline silicon, microcrystalline silicon, or polycrystalline silicon; (b) placing the substrate in a PE-CVD chamber; (c) introducing into the chamber a source gas comprising a volatile silicone precursor and at least one oxidant gas selected from the group consisting of oxygen, ozone, hydrogen peroxide, and nitrous oxide; and (d) applying radio frequency power to the chamber; so that a layer of organosilicate glass is deposited on the silicon film and substrate.

The above-described method may further comprise the steps of: (a) patterning the organosilicate glass layer to expose the silicon layer; (b) providing a layer of doped silicon on the exposed silicon, by doping the exposed silicon by ion implantation or by depositing a layer of doped silicon; (c) depositing a layer of an electrode material; and (d) patterning the electrode material so as to form gate, source, and drain electrodes.

All of the above methods may further comprise the step of depositing a passivating layer of organosilicate glass on any exposed amorphous hydrogenated silicon.

In certain embodiments, a gate insulator layer of the present invention comprises a hybrid silica-silicone material, also known in the art as an organosilicate glass. Plasma-enhanced CVD (PE-CVD) is preferably used for deposition of the layer of hybrid silica-silicone material. PE-CVD may be desirable for various reasons, including low temperature deposition (e.g., less than 150° C.), uniform coating formation, and controllable process parameters. Various PE-CVD processes which are suitable for use in the present invention are known in the art, including those that use radio frequency (RF), microwave, or direct current (DC) energy to generate the plasma.

The volatile silicone precursor may be any material that is capable of forming a layer of organosilicate glass when deposited by chemical vapor deposition. Various such precursor materials are suitable for use in the present invention, and are chosen for their various characteristics. For example, a precursor material may be chosen for its content of chemical elements, the stoichiometric ratios of the chemical elements present, and/or the polymeric and non-polymeric materials that are formed under PECVD. The siloxanes are a class of compounds particularly suitable for use as the precursor material. Representative examples of siloxane compounds include hexamethyldisiloxane (HMDSO) and dimethyldimethoxysilane. When deposited by PECVD in the presence of an oxidant, these siloxane compounds are able to form both silicone polymers and silicon dioxide, and under appropriate conditions a hybrid of the two, an organosilicate glass, is deposited. The precursor material may also be chosen on the basis of other characteristics such as cost, non-toxicity, viscosity, freezing point, volatility, and the available levels of purity.

Other organosilicon compounds suitable for use as a precursor material include, but are not limited to, methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene, and fluorinated derivatives of these compounds. Phenyl-containing organosilicon compounds suitable for use as a precursor material include: dimethylphenylsilane and diphenylmethylsilane. Oxygen-containing organosilicon compounds suitable for use as a precursor material include: dimethyldimethoxysilane; tetramethydisiloxane, 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethyltrisiloxane, octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane, decamethylcyclopentasiloxane, 2,2,-dialkyl-1,3-dioxa-2-silacyclopentanes (where alkyl is methyl, ethyl, propyl, or isopropyl), and fluorinated derivatives of these compounds.

Preferably, the volatile silicone precursor is tetramethydisiloxane, hexamethyldisiloxane, octamethyltrisiloxane, hexamethylcyclotrisiloxane, octamethylcyclotetrasiloxane, decamethylcyclopentasiloxane, or a 2,2,-dialkyl-1,3-dioxa-2-silacyclopentanes. Most preferred is hexamethyldisiloxane.

The organosilicate glass is preferably deposited by plasma-enhanced chemical vapor deposition (PE-CVD) from a gas mixture comprising a volatile silicone precursor, as described above, and an oxidant gas which is preferably oxygen. Optionally, the precursor gas mixture may include one or more volatile sources of nitrogen, such as for example nitrogen gas, ammonia, organosilazanes, and silylated amine compounds.

Nitrogen-containing organosilicon compounds suitable for use as a nitrogen source material include, but are not limited to, hexamethyldisilazane; divinyltetramethyldisilazane; hexamethylcyclotrisilazane; dimethylbis(N-methylacetamido)silane; dimethylbis-(N-ethylacetamido)silane; methylvinylbis(N-methylacetamido)silane; methylvinylbis(N-butylacetamido)silane; methyltris(N-phenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

When deposited by PECVD, the precursor material may form various types of polymeric materials in various amounts, depending upon the type of precursor material, the quantity and nature of the oxidant and other reactive gases, such as nitrogen donors, and the physical reaction conditions. Where organosilicon compounds are used as the precursor material, the deposited hybrid layer may include, for example, polymer chains incorporating Si—O bonds, Si—C bonds, and/or Si—O—C bonds to form polysiloxanes, polycarbosilanes, and polysilanes, and varying proportions of a predominantly inorganic silica-like phase. For example, where organosilicon compounds are used as the precursor material in combination with an oxygen-containing oxidant gas, the non-polymeric material may include silicon oxides, such as SiO, SiO₂, and mixed-valence oxides SiOₓ. When deposited with a nitrogen-containing reactant gas, the non-polymeric material may also include silicon nitrides (SiNₓ), silicon oxycarbide, and silicon oxynitrides.

When using PE-CVD, one or more precursor materials may be used in conjunction with one or more reactant gases that react with the precursor material in the PE-CVD process. The use of reactant gases in PE-CVD is known in the art, and various reactant gases are suitable for use in the present invention, including oxygen-containing gases (e.g., O₂, ozone, hydrogen peroxide, nitrous oxide, organic peroxides and hydroperoxides, and water) and nitrogen-containing gases (e.g., ammonia and hexamethyldisilazane). The reactant gas may be used to vary the stoichiometric ratios of the chemical elements present in the reaction mixture. For example, when a siloxane precursor material is used with an oxygen or nitrogen-containing reactant gas, the reactant gas will change the stoichiometric ratios of oxygen or nitrogen in relation to silicon and carbon in the reaction mixture. This stoichiometric relation between the various chemical elements (e.g., silicon, carbon, oxygen, nitrogen) in the reaction mixture may be varied in several ways. The concentrations of the precursor materials and reactant gases in the reaction may be controlled by varying the flow rates of the precursor material and reactant gases into the reaction. Another way is to vary the type of precursor materials or reactant gases used in the reaction. The use of a cyclic siloxane, for example, in place of the analogous linear siloxane, will result in a lower ratio of carbon to silicon in the oganosilicate glass.

Changing the stoichiometric ratios of the elements in the reaction mixture can affect the properties and relative amounts of the polymeric and non-polymeric materials in the deposited hybrid layer. For example, a siloxane gas may be combined with varying amounts of oxygen to adjust the relative amounts of silica-like and silicone-like material in the hybrid layer. By increasing the stoichiometric ratio of oxygen in relation to silicon or carbon, the amount of silica-like material may be increased. Similarly, by reducing the stoichiometric ratio of oxygen, the relative amount of carbon-containing silicone-like material may be increased. The composition of the hybrid layer may also be varied by adjusting other reaction conditions. For example, in the case of PE-CVD, process parameters such as RF power and frequency, deposition pressure, deposition time, and gas flow rates can be varied.

In the present invention, the organosilicate glasses employed as gate insulator layers are rich in the silica-like phase. This is most conveniently achieved by depositing the layer from an oxygen-rich precursor gas mixture. For example, when using oxygen as the oxidant gas and hexamethyldisiloxane as the volatile silicone precursor in the present invention, the volume flow percentage of silicone precursor in oxygen, as measured in standard cubic centimeters per minute, is between 0.1% and 10%. The volume flow ratio corresponds approximately to the mole ratio of the two molecular species in the CVD chamber during the deposition process. Preferably, the volume flow percentage of silicone precursor in oxygen is between 0.5% and 8%, more preferably it is between 1% and 6%, and still more preferably it is between 2% and 5%. These figures may be adjusted, as necessary, to account for silicone precursors having different molecular weights, different chemical compositions, and correspondingly different silicon and carbon contents per standard cubic centimeter. In the case of hexamethyldisiloxane, “oxygen-rich” conditions refer to relative oxygen flow rates greater than about 25:1 relative to the flow of hexamethydisiloxame. The percentage of HMDSO is most preferably between 2% and 4%. FIG. 13 shows how the molar ratio of oxygen to hexamethyldisiloxane affects the breakdown voltage of the resulting hybrid dielectric.

Thus, by using the methods of the present invention, it is possible to form a layer of hybrid organosilicate glass having both polymeric (silicone-like) and non-polymeric (silica-like) components, and having bulk characteristics suitable for use as a gate insulator.

The organosilicate glass gate insulator material of the invention comprises from about 70% to about 95% silicon dioxide (silica-like material) and from about 30% to about 5% siloxane polymers (silicone-like material). As used herein, percentages of silicon dioxide and siloxane polymers refer to the molar ratio of silicon atoms bonded only to oxygen and silicon atoms bonded to at least one carbon. This ratio may be determined by means of various techniques appropriate to surface and thin-film chemical and elemental analysis, such as infrared absorption spectroscopy, Raman scattering spectroscopy, electron spectroscopy for chemical analysis (ESCA), Rutherford backscattering, and the like.

The methods of the invention provide a gate insulator layer that is particularly suitable for use in thin-film transistors (TFTs). The gate insulator layer can be made extremely thin, with excellent uniformity and a very low level of defects, which are desirable properties in the manufacture of display devices based on very large arrays of TFTs. The gate insulator layer may have a thickness of less than 300 nm, and in some cases, less than 250 nm, and in some cases, less than 150 nm. This is a considerable improvement over silicon nitride gate dielectrics, which typically require at least a 300 nm thickness to perform effectively. (See, for example, Lin et al., “Amorphous silicon thin-film transistors with field-effect mobilities of 2 cm²/V·s for electrons and 0.1 cm²/V·s for holes,” Appl. Phys. Lett. 94:162105 (April 2009)). TFT's of the present invention may be able to perform so effectively with very thin gate insulator thicknesses because the organosilicate glass hybrid material has fewer microcracks that permit current leakage. In contrast, brittle materials such as SiNₓ and SiO₂ are known to suffer from such microcracks, resulting in current leakage. (See, for example, Lin Han et al., “A New Gate Dielectric for Highly Stable Amorphous-Silicon Thin-Film Transistors With˜1.5-cm²/V·s Electron Field-Effect Mobility,” IEEE Electron Device Lett. 30:5, pp. 502-504 (May 2009)). The gate insulators of the invention may form strong bonds to other materials used in the making of TFTs, and give rise to low numbers of interface states.

Because of the low temperatures involved in PE-CVD, the methods of the invention are particularly suitable for the manufacture of organic TFTs, which employ relatively heat-sensitive organic semiconductor materials as the active layer. The hybrid dielectric of the present invention has excellent properties when deposited by PE-CVD on substrates that are held at room temperature. This material is of particular advantage for thin film transistors used in flexible electronics, because it does not crack easily, unlike the conventional gate insulators, silicon nitride and silicon dioxide, which are brittle materials. Because the hybrid dielectric can be deposited at lower temperatures (e.g., about room temperature), there may be no contraction upon cooling, and a bonded layer does not generate stress through differential contraction at the interface with other layers. Since the coefficient of thermal expansion of the substrate need not be closely matched, the hybrid dielectrics of the invention make it feasible to build TFTs on a wider variety of substrate materials, in particular transparent, flexible plastic substrates that are desirable for use in lightweight, flexible LCD and OLED displays.

The invention also provides a field-effect transistor comprising a gate insulator material disposed between a gate electrode and a semiconductor active layer, wherein the gate insulator material comprises, or preferably consists essentially of, an organosilicate glass as described above. In this context, “consisting essentially of” means that there are no materials present, other than the silicon, carbon, hydrogen, oxygen, and optionally nitrogen provided by the volatile precursor gases describe herein, that have a functionally relevant effect on the insulating, dielectric, and barrier state properties of the organosilicate glass insulator layers of the invention. In preferred embodiments, the gate insulator material consists of an organosilicate glass as describe above, which may optionally have a nitrogen component.

Semiconductors suitable for the TFTs of the invention are all semiconductors known in the art, including but not limited to amorphous silicon, nanocrystalline silicon, microcrystalline silicon, polycrystalline silicon, zinc oxide, zinc tin oxide, and zinc gallium oxide. In view if the present state of the art, amorphous silicon is preferred, and hydrogenated amorphous silicon is more preferred.

Organic semiconductor materials for the organic semiconductor layer of the organic thin-film transistor of the invention may be any such materials as are known in the art. Most commonly, it-conjugated materials are used. Examples of the π-conjugated materials include but are not limited to polypyrroles such as polypyrrole, poly(N-substituted pyrrole), poly(3-substituted pyrrole), and poly(3,4-disubstituted pyrrole); polythiophenes such as polythiophene, poly(3-substituted thiophene), poly(3,4-disubstituted thiophene), and polybenzothiophene; polyisothianaphthenes such as polyisothianaphthene; polythienylenevinylenes such as polythienylenevinylene; poly(p-phenylenevinylenes) such as poly(p-phenylenevinylene); polyanilines such as polyaniline, poly(N-substituted aniline), poly(3-substituted aniline), and poly(2,3-substituted aniline); polyacetylenes such as polyacetylene; polydiacetylenes such as polydiacetylene; polyazulenes such as polyazulene; polypyrenes such as polypyrene; polycarbazoles such as polycarbazole and poly(N-substituted carbazole), polyselenophenes such as polyselenophene; polyfurans such as polyfuran and polybenzofuran; poly(p-phenylenes) such as poly(p-phenylene); polyindoles such as polyindole; polypyridazines such as polypyridazine; polyacenes such as naphthacene, pentacene, hexacene, heptacene, dibenzopentacene, tertabenzopentacene, pyrene, dibenzopyrene, chrysene, perylene, coronene, terylene, ovalene, quoterylene, and circumanthracene; derivatives (such as triphenodioxazine, triphenodithiazine, hexacene-6,15-quinone) in which some of carbon atoms of polyacenes are substituted with atoms such as N, S, and O or with a functional group such as a carbonyl group; polymers such as polyvinyl carbazoles, polyphenylene sulfide, and polyvinylene sulfide.

Further, oligomers having repeating units in the same manner as in the above polymers, for example, thiophene hexamers including α-sexithiophene, α,ω-dihexyl-α-sexithiophene, α,ω-dihexyl-α-quinquethiophene, and α,ω-bis(3-butoxypropyl)-α-sexithiophene, or styrylbenzene derivatives, can be suitably employed.

Further, listed are metallophthalocyanines such as copper phthalocyanine and fluorine-substituted copper phthalocyanines; tetracarboxylic acid diimides of condensed ring compounds including naphthalene tetracarboxylic acid imides such as naphthalene 1,4,5,8-teracarboxylic acid diimide, N,N′-bis(4-trifluoromethylbenzyl)naphthalene 1,4,5,8-tretracarboxylic acid diimide, N,N′-bis(1H,1H-perfluoroctyl)naphthalene 1,4,5,8-tetracarboxylic acid diimide derivatives, N,N′-bis(1H,1H-perfluorobutyl)naphthalene 1,4,5,8-tetracarboxylic acid diimide derivatives, N,N′-dioctylnaphthalene 1,4,5,8-tetracarboxylic acid diimide derivatives, and naphthalene 2,3,6,7-tetracarboxylic acid diimides, and anthracene tetracarbocylic acid diimides such as anthracene 2,3,6,7-tetracarboxylic acid diimides; fullerenes such as C₆₀, C₇₀, C₇₆, C₇₈, and C₈₄; carbon nanotubes such as SWNT; and dyes such as merocyanines and hemicyanines.

Of these π conjugated compounds, preferably employed is at least one selected from the group consisting of oligomers which have thiophene, vinylene, thienylenevinylene, phenylenevinylene, p-phenylene, their substitution product or at least two kinds thereof as a repeating unit and have a repeating unit number n of from 4 to 10, polymers which have the same unit as above and a repeating unit number n of at least 20, condensed polycyclic aromatic compounds such as pentacene, fullerenes, condensed cyclic tetracarboxylic acid diimides of condensed ring compounds, and metallo-phthalocyanines.

Further employed as other materials for organic semiconductors may be organic molecular complexes such as a tetrathiafulvalene (TTF)-tetracyanoquinodimethane (TCNQ) complex, a bisethylenetetrathiafulvalene (BEDTTTF)-perchloric acid complex, a BEDTTTF-iodine complex, and a TCNQ-iodine complex.

The organic semiconductor layer may be subjected to a doping treatment by incorporating in the layer materials an electron accepting molecule (acceptor) or an electron donating molecule (donor), including but not limited to benzoquinone derivatives, tetracyanoethylene, tetracyanoquinodimethane; substituted amines such as phenylenediamine; anthracene, benzoanthracene and substituted benzoanthracenes, pyrene and substituted pyrenes; carbazole and its derivatives; and tetrathiafulvalene and its derivatives.

The invention also provides a method of forming a transistor having an organosilicate glass gate insulator layer by plasma-enhanced chemical vapor deposition, comprising the steps of: (a) depositing a gate electrode on a substrate; (b) mounting the substrate with gate electrode in a CVD chamber; (c) introducing into the chamber a source gas comprising a volatile silicone precursor and at least one oxidant gas selected from the group consisting of oxygen, ozone, hydrogen peroxide, and nitrous oxide; and (d) applying radio frequency, microwave frequency, or DC power to the chamber. A layer of organosilicate glass is thereby deposited on the gate electrode and substrate, which serves as the gate insulator.

Suitable substrates include glass, metal, and high-strength polymer film and foil substrates known in the art. High-strength polymer film substrates are desirable for making flexible displays, and include for example polyethylene terephthalate (PET) and polyimide foils and films. The substrate is preferably coated with a suitable subbing layer, as is known in the art. For example, with a glass substrate, silicon nitride or an organosilicate glass (which may be an organosilicate glass as described herein), may be employed. Polymer subbing layers have been developed for various other substrates such as metal and polymer substrates.

The method further comprises the step of depositing a layer of the active semiconductor material, preferably silicon, and more preferably amorphous hydrogenated silicon. A layer of doped amorphous hydrogenated silicon is deposited onto the amorphous hydrogenated silicon. Finally, a source/drain conductor layer is deposited, and this layer is patterned so as to produce source and drain electrodes. Suitable conductors are any of those known in the art, including but not limited to indium-tin oxide, chromium, aluminum, copper, and the like.

The patterning of the various layers, as carried out in practicing the present invention, may be accomplished by any of the various means known in the art. Methods based on photolithography may be employed, and those skilled in the art will be familiar with the use of appropriate resists and etching methods. The patterning methods may include the self-alignment of layers to previously patterned layers. Etching methods include, but are not limited to, various wet chemical and plasma methods. Suitable non-limiting methods are indicated in the examples below. Damascene methods may be employed where appropriate, for example, in laying down fine copper conductors.

An alternative method of forming a transistor having an organosilicate glass gate insulator layer by plasma-enhanced chemical vapor deposition, is also provided, which comprises the steps of: (a) depositing a source/drain conductor layer on a substrate; (b) depositing a layer of doped amorphous hydrogenated silicon on the source/drain conductor layer; (c) patterning the doped amorphous hydrogenated silicon layer and source/drain conductor layer, so as to form separate source and drain electrodes; (d) depositing a layer of amorphous hydrogenated silicon; (e) mounting the substrate in a CVD chamber; (f) introducing into the chamber a source gas comprising a volatile silicone precursor and at least one oxidant gas selected from the groups consisting of oxygen, ozone, hydrogen peroxide, and nitrous oxide; and (g) applying radio frequency, microwave frequency, or DC power to the chamber. In this way, a layer of organosilicate glass is deposited on the amorphous hydrogenated silicon layer. The transistor is completed by depositing a gate conductor layer; and patterning the gate conductor layer so as to form a gate electrode. The substrate is preferably coated with a suitable subbing or passivation layer, as is known in the art. For example with a glass substrate, silicon nitride, or an organosilicate glass which may be an organosilicate glass as described herein, may be employed. Polymer subbing or passivation layers have been developed for various other substrates such as metal and polymer substrates.

The organosilicate glass, amorphous hydrogenated silicon, and doped amorphous hydrogenated silicon layers are then patterned so as to expose the source and drain electrodes. Industry-standard methods for patterning and etching, such as reactive ion etching, that are suitable for silica are generally suitable for the hybrid OSG dielectric material of the present invention.

Yet another method of forming a transistor having an organosilicate glass gate insulator is provided, which comprises the steps of: (a) preparing, on a substrate, a film of amorphous silicon, nanocrystalline silicon, microcrystalline silicon, or polycrystalline silicon; (b) mounting the substrate in a CVD chamber; (c) introducing into the chamber a source gas comprising a volatile silicone precursor and an oxidant gas as describe above; and (d) applying radio frequency power to the chamber; whereby a layer of organosilicate glass is deposited on the silicon film and substrate. The substrate is preferably coated with a suitable subbing or passivating layer, as is known in the art. For example with a glass substrate, silicon nitride, or an organosilicate glass which may be an organosilicate glass as described herein, may be employed. Polymer subbing layers have been developed for various other substrates such as metal and resin substrates.

The method further comprises the steps of: (a) patterning the organosilicate glass layer to expose the silicon layer; (b) providing a layer of doped silicon on the exposed silicon, by doping the exposed silicon by ion implantation or by depositing a layer of doped silicon; (c) depositing a layer of an electrode material; and (d) patterning the electrode material so as to form gate, source, and drain electrodes.

The invention may also provide transistors made by any of the above-described methods. The following descriptions are intended to be exemplary of the invention, and do not represent the limits of the invention or limitations to the scope of the appended claims.

### EXAMPLES

### 1.0 Deposition of the Hybrid Gate Insulator Layer (“the Gate Dielectric”)

The hybrid is deposited by plasma-enhanced chemical vapor deposition (PE-CVD) in a single-chamber reactor, denoted below as the “small PE-CVD.” In the course of development of the hybrid material, the small PE-CVD was re-configured several times. The hybrid gate dielectric was deposited in two configurations, which differ in electrode surface area and gas feed as explained below. PE-CVD of the hybrid dielectric under oxygen-rich conditions (i.e., flow rates greater than about 25:1 relative to the flow of hexamethydidsiloxane) was found to produce a material with a dielectric breakdown field E_{bd}≅8 MV/cm, close to that of thermal SiO₂. (See FIG. 13.)

### 1.1 PECVD Configuration

102 cm² surface area of the powered electrode and of the grid over the gas feed plenum. Source gas flow rates: Oxygen 42 sccm; hexamethyldisiloxane (HMDSO) 1.17 sccm; RF frequency: 13.56 MHz; RF power used for deposition: 50 W (0.5 W/cm²); deposition pressure: ˜120 mtorr=16 Pa. Substrate temperature was nominal room temperature.

### 1.2 Alternative PECVD Configuration

An alternative PECVD configuration used 182 cm² surface area of powered electrode, and 7.5 cm diameter of the gas feed ring. The source gas flow rates were: O₂ 33 sccm; HMDSO 1.25 sccm; RF frequency was: 13.56 MHz; deposition power was 70 W (0.38 W/cm²); deposition pressure was ˜115 mtorr=15 Pa. Substrate temperature was nominal room temperature to 310° C.

### 2.0 Thin-Film Transistor (TFT) Fabrication Process Sequences

The process sequences for two different TFT geometries are described below. Both use amorphous hydrogenated silicon (a—Si:H or a—Si) for the channel semiconductor. The first is the conventional inverted-staggered geometry, which was made on glass and on Kapton™ polyimide foil substrates; the second is the top-gate staggered geometry.

The examples herein were carried out using two PE-CVD apparatuses. One is the “small PE-CVD” described above, which is used for deposition of the organosilicate glass (OSG) gate dielectric, back channel passivation, and substrate passivation layers. The other is a four-chamber PE-CVD system, in which all other TFT layers are deposited: silicon nitride (SiNₓ) used as passivation layer (and as gate dielectric in conventional a—Si TFTs); undoped amorphous hydrogenated silicon (a—Si:H or a—Si) for the semiconducting channel of the TFT; and a highly-doped n-type a—Si:H layer used for source and drain contacts.

Working with two different PE-CVD apparatuses requires that the samples be transferred forth and back through the atmosphere, which in thin-film electronics is considered to be very undesirable. The reason is that exposure to the atmosphere changes the exposed surfaces (which become interfaces after the subsequent layer has been deposited) in an irreproducible fashion. The most sensitive interface is that between the gate insulator and the semiconductor channel, in this case between the organosilicate glass and the a—Si:H, because conducting electrons move along this interface. Conducting the process in two different PE-CVD systems exposes this interface to the atmosphere, and it is surprising that high field-effect mobilities can be obtained with this process. It is possible that the variations in field-effect mobility between separate TFT process runs are due to a poorly-reproducible interface resulting from the transfer between chambers.

Described below are processes for fabricating inverted-staggered TFTs on glass (2.1) and Kapton polyimide foil (2.2) substrates. In the drawings, the OSG layer may also be designated as “Hybrid.”

### 2.1 Inverted-Staggered Geometry on Glass

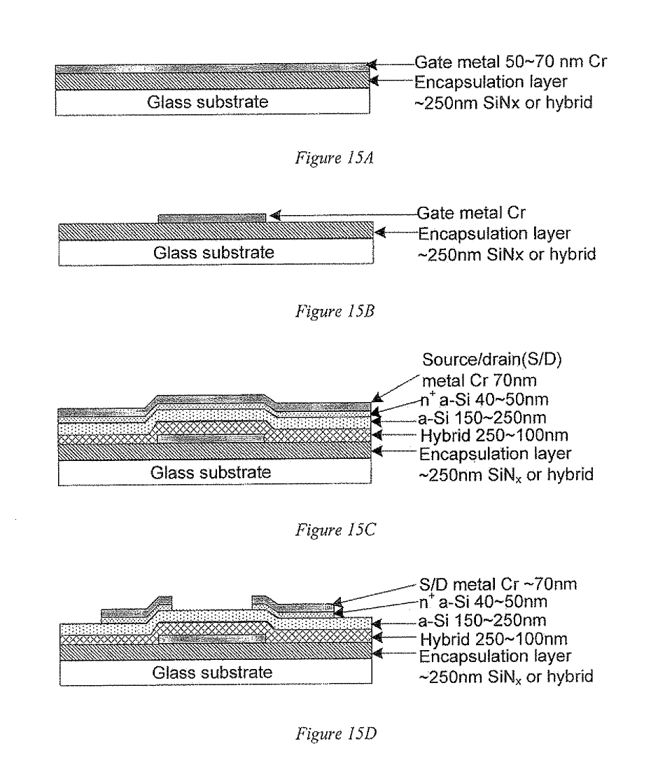

The glass substrate was coated with about 250 nm SiNₓ in the four-chamber PECVD at 150° C. or 200° C., or with about 250 nm OSG in the small PECVD at room temperature. Then 50 to 70 nm of Cr gate contact metal was thermally evaporated. (See FIG. 15A.). Mask #1 was used for gate patterning. Spin on and pre-bake photoresist, expose resist to UV light through a photomask with the gate metal pattern, develop the resist, wet etch the chromium with chromium etchant, strip the remaining photoresist. (See FIG. 15B.) The sample was loaded in the small PECVD, and about 100-250 nm OSG was deposited (sometimes followed by 3 minutes oxygen plasma). Then the sample was transferred to the four-chamber PECVD for the deposition of undoped a—Si:H and n⁺ a—Si:H at 150° C. or ˜250° C. Prior to the deposition of the a—Si:H, Ar plasma was run for 3 minutes to clean the surface. Then ˜70 nm Cr for source and drain metal contact was deposited in the thermal evaporator. (See FIG. 15C.)

Mask #2 was used for source and drain (S/D) patterning. Photolithography was as described under Mask #1. Chromium was wet etched with Cr etchant, and n⁺ a—Si was removed by reactive ion etching (RIE). (See FIG. 15D). Mask #3 was used for active area (a—Si island) patterning. Photolithography was performed as described for Mask #1. The a—Si was removed by RIE. Mask #4 was used to make via openings in the hybrid for the gate electrode contact. Photolithography was performed as described for Mask #1. The OSG was etched with RIE.

### 2.2 Inverted-Staggered Geometry on 50-μm Thick Kapton™ E Polyimide Foil

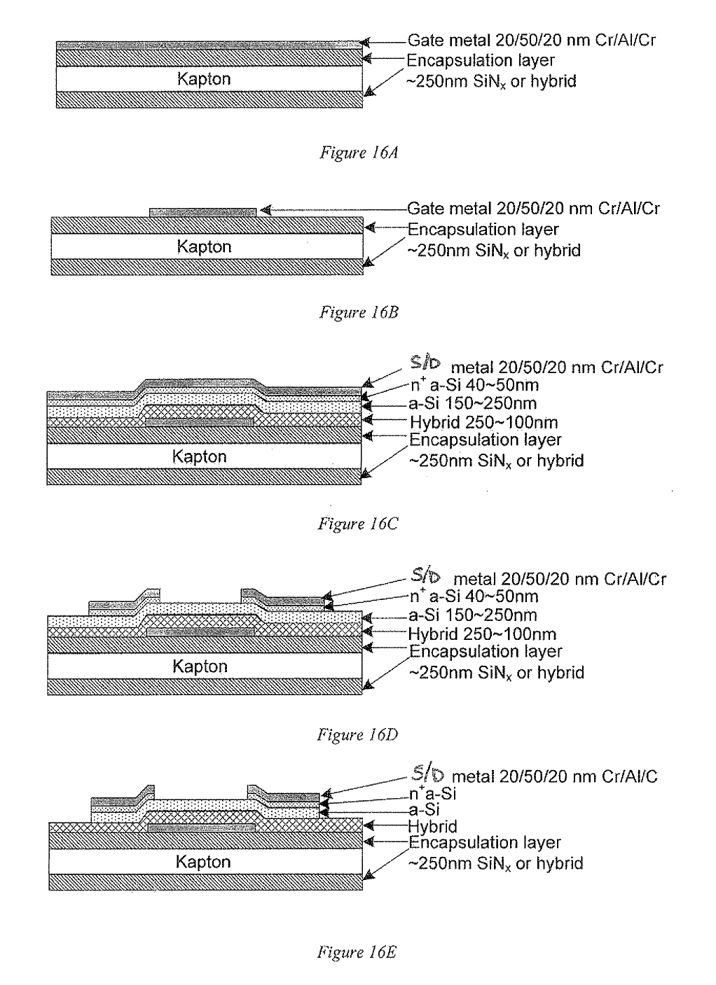

A Kapton™ polyimide foil substrate was coated with about 250 nm SiNₓ in the four-chamber PECVD at 150° C. or 200° C., or with about 250 nm OSG in the small PECVD at room temperature. Then 20/50/20 nm tri-layer Cr/Al/Cr gate contact metal was thermally evaporated. (See FIG. 16A.)

Mask #1 was used for gate patterning. Spin on and pre-bake photoresist, expose resist to UV light through a photomask with the gate metal pattern, develop the resist, wet etch the Cr/Al/Cr with Cr and Al etchants, strip the remaining photoresist. (See FIG. 16B.) The sample was loaded in the small PECVD, and about 100-250 nm OSG was deposited (sometimes followed by 3 minutes oxygen plasma). Then the sample was transferred to the four-chamber PECVD for the deposition of a—Si and n+ a—Si at 150° C. or ˜250° C. Before the deposition of a—Si, 3 minutes of Ar plasma was run to clean the surface. Then 20/50/20 nm Cr/Al/Cr for source and drain metal contact was deposited in the thermal evaporator. (See FIG. 16C.)

Mask #2 was used for source and drain (S/D) patterning. Photolithography was performed as described for Mask #1. Cr and Al were wet etched with Cr and Al etchants, and n⁺ a—Si was removed by reactive ion etching (RIE). (See FIG. 16D.) Mask #3 was used for active area (a—Si island) patterning. Photolithography was performed as described for Mask #1. The a—Si was removed by RIE. (See FIG. 16E.). Mask #4 was used to make via openings in the hybrid for gate electrode contact. Photolithography was performed as described for Mask #1. The OSG was etched with RIE.

### 2.3 Top-Gate Staggered Geometry On Glass

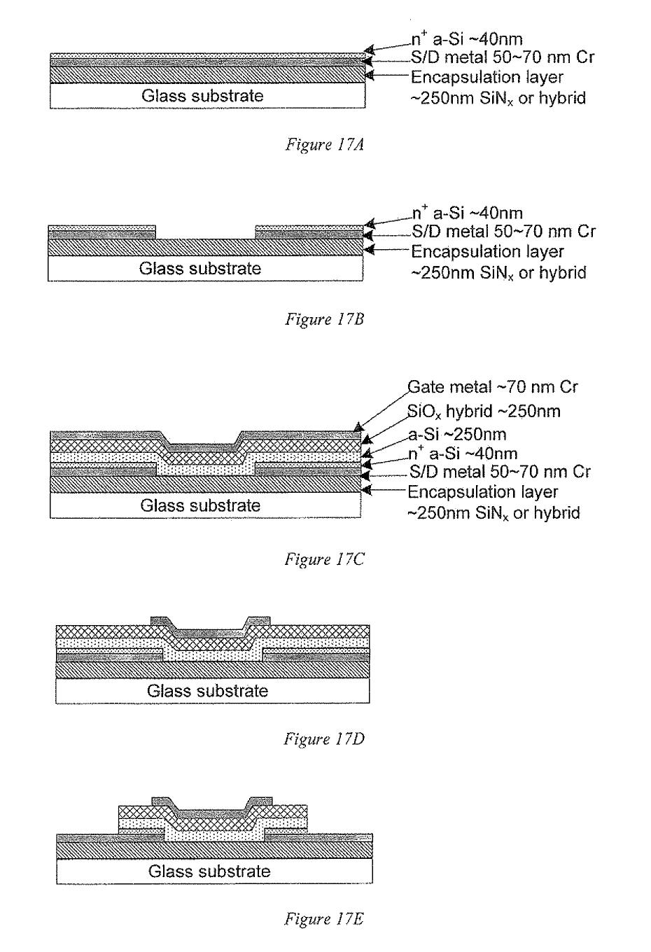

A glass substrate was coated with about 250 nm SiNₓ in the four-chamber PECVD at 150° C. or 200° C., or with about 250 nm hybrid in the small PECVD at room temperature. Then 50 to 70 nm of Cr source and drain contact metal was thermally evaporated. After transfer to the four-chamber PECVD, approximately 40 nm of n⁺ a—Si for source and drain layer was deposited. (See FIG. 17A.)

Mask #1 was used for source and drain (S/D) patterning. Photolithography was performed as described for Mask #1 of Section 2.1 above. The n⁺ a—Si was etched by reactive ion etching (RIE), and the chromium was wet etched with Cr etchant. (See FIG. 17B.) A 250-nm layer of a—Si was deposited in the four-chamber PECVD. A 250 nm OSG layer for the gate dielectric was then deposited in the single-chamber PECVD. Finally 70 nm of Cr was thermally evaporated for the gate electrode. (See FIG. 17C.)

Mask #2 was used for gate patterning. Spun on and pre-baked photoresist, exposed resist to UV light through a photomask with the gate metal pattern, developed the resist, wet etched the Cr with Cr etchant, stripped the remaining photoresist. (See FIG. 17D.) Mask #3 was used for active area (a—Si island) patterning. Photolithography was performed as described for Mask #1. The OSG and a—Si were removed by RIE. (See FIG. 17E.)

### 2.4 Inverted-Staggered Geometry on Glass, With Back Channel Passivation

The glass substrate was coated with about 250 nm SiNₓ in the four-chamber PECVD at 150° C. or 200° C., followed by thermal evaporation of a 60 nm layer of Cr metal as gate contact.

Mask #1 was used for gate patterning. Spin on and pre-bake photoresist, expose resist to UV light through a photomask with the gate metal pattern, develop the resist, wet etch the chromium with chromium etchant, strip the remaining photoresist. The sample was loaded in the small PECVD, and a 100 nm layer of OSG was deposited. The sample was transferred to the four-chamber PECVD for the deposition of 150 nm of a—Si:H at 250° C., then returned to the small PECVD, and a 150 nm layer of OSG was deposited.

Using Mask #2, the 150 nm OSG layer is then patterned to form the back-channel passivation layer. The sample was dipped into 1/100 diluted buffered oxide etch (BOE), an HF based aqueous etchant, for 20 seconds to remove any oxide, then immediately loaded into the four-chamber PECVD. A 40-nm layer of n⁺-doped a—Si:H was then deposited at 250° C. to provide the source/drain layer. (A 3-minute long Ar plasma may be used to clean the sample surface prior to the deposition of n+ a—Si.) Source and drain contacts were provided by a Cr/Al/Cr sandwich (20/200/20 nm), deposited by sequential thermal evaporation of the metals.

Mask #3 was used for source and drain (S/D) patterning. Photolithography was performed as described above for Mask #1. Cr/Al/Cr was wet etched with Cr and Al etchants. Mask #4 was used for active area (a—Si island) patterning. Photolithography was performed as described above for Mask #1. The a—Si was removed by RIE to isolate source and drain, as described above. Mask #5 was used for making via openings were made in the hybrid for gate electrode contact. Photolithography was performed as described above for Mask #1. OSG and a—Si:H were etched with RIE.

### 3. Transistor Fabrication and Evaluation

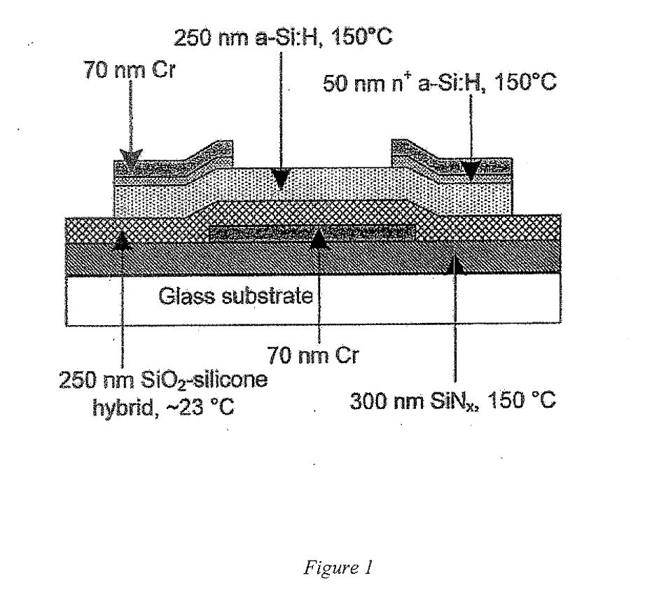

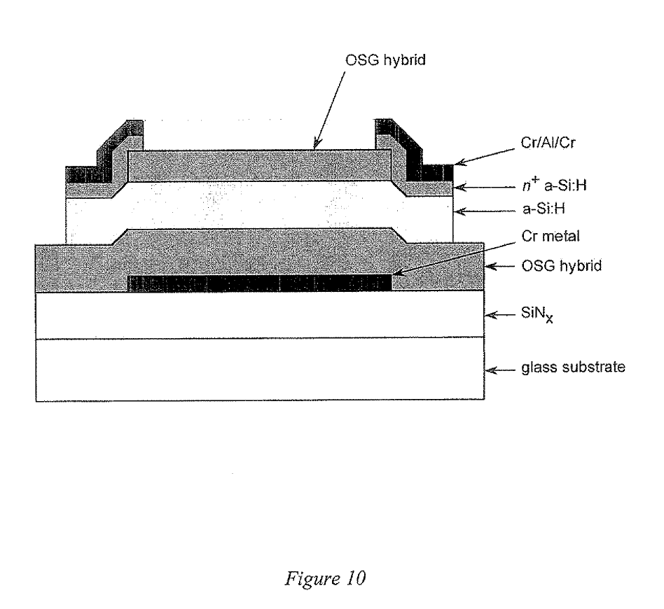

Using the methods described above, a—Si: H TFTs were prepared, mostly in the conventional inverted-staggered geometry on glass substrates. The cross-sectional view of this geometry is shown in FIGS. 1 and 10. Fabrication, evaluation, and characteristics of representative examples are described below. These samples are designated as TFT 1, TFT 2, TFT 3, and TFT 4. A series of TFTs was also fabricated on polyimide foil for stress and flexibility testing, and TFTs with the OSG gate dielectric in the top-gate co-planar geometry were fabricated as a demonstration of the generality of the invention. The examples illustrate some of the variations in process temperatures, substrates, geometry, and thickness of gate insulator, the use of the hybrid material for gate dielectric, back channel passivation, and substrate passivation, and show the improved electrical and physical properties that can be obtained.

TFT 1 was processed at low temperature and had a 250-nm thick OSG gate insulator, which is close to the thickness of 300 nm of the conventionally-used SiNₓ insulator. TFT 2 was processed at high temperature and had a 100-nm OSG insulator, which is extremely thin by the standards of the conventionally-used SiNₓ insulators. TFT 3 was processed at low temperature, had a 100-nm (thin) OSG gate insulator, and featured a 150-nm thick OSG back channel passivating layer. TFT 4 was processed at low temperature, and featured a flexible substrate with a hybrid OSG passivation layer, a hybrid OSG gate insulator, and a hybrid OSG back channel passivation layer.

For the fabrication of TFT 1 the glass substrate was coated prior to TFT growth with a 300-nm thick layer of SiNₓ, deposited by PE-CVD at 150° C. 70 nm of Cr was evaporated as gate electrode. After the gate electrode was patterned, in the specific example of FIG. 1, a 250-nm thick OSG layer was deposited at nominal room temperature in a single-chamber PE-CVD machine. The source gases for SiO₂-silicone hybrid OSG deposition were HMDSO and oxygen, which are environmentally friendly and low-cost. The properties of the OSG material fall between those of thermal oxide and plasma-polymerized HMDSO. (L. Han, P. Mandlik, J. Gartside, and S. Wagner, Mater. Res. Soc. Symp. Proc., 2008, A18.3.) The sample was transferred to a four-chamber PE-CVD system to deposit a 300-nm thick a—Si:H channel layer and a 50-nm n⁺ a—Si: H source/drain contact layer. The source/drain contacts (70 nm Cr) were made by thermal evaporation.

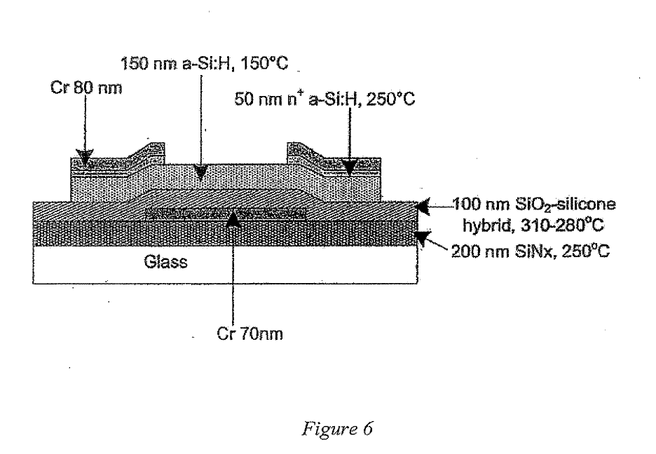

For the fabrication of TFT 2 (FIG. 6), the glass substrate was coated prior to TFT growth with a 200 nm thick layer of SiNₓ, deposited by PE-CVD at 250° C. A 70 nm layer of Cr was evaporated as gate electrode. After the gate electrode was patterned, a 100-nm thick OSG layer was deposited at a substrate temperature of 310° C. to 280° C. in a single-chamber PE-CVD machine. The sample was then transferred to a four-chamber PE-CVD system to deposit a 150-nm thick a—Si:H channel layer and a 50-nm n⁺ a—Si: H source/drain contact layer. The source/drain contacts were made of thermally evaporated 70 nm Cr.

For the fabrication of TFT 3 (FIG. 10), the glass substrate was coated prior to TFT growth with a 250 nm thick layer of SiNₓ, deposited by PE-CVD at 250° C. A 70 nm layer of Cr was evaporated as gate electrode. After the gate electrode was patterned, an approximately 100-nm thick OSG layer was deposited at room temperature in a single-chamber PE-CVD machine. The sample was then transferred to a four-chamber PE-CVD system to deposit a 150-nm thick a—Si:H channel layer. A 150 nm OSG layer was then laid down, again at room temperature, followed by the patterning of the back-channel passivation layer. Then the sample was dipped into 1/100 diluted BOE for 20 seconds to remove any native oxide, and transferred immediately to the four-chamber PECVD system for deposition of 40-nm n+ a—Si:H source/drain layer. The source/drain contacts, a Cr/Al/Cr (20/200/20 nm) sandwich, were applied by thermal evaporation. Patterning of source and drain, isolation of islands, and opening of vias to gate electrodes, were carried out by etching in the usual manner.

For the fabrication of TFT 4, a 50 μm polyimide foil substrate was encapsulated by room-temperature PE-CVD deposition of a 250 nm layer of OSG hybrid on both faces. A Cr/Al/Cr (15/40/15 nm) metal sandwich was thermally evaporated and patterned for gate electrodes. A 150-nm thick OSG hybrid gate dielectric was deposited at room temperature by PE-CVD, followed by a 150 nm layer of a—Si:H deposited at 150° C. A 150-nm thick OSG hybrid layer was then deposited for back-channel passivation. After patterning, a 40 nm n+ a—Si:H source/drain layer was deposited at 150° C., followed by thermal evaporation of a 15/40/15 nm Cr/Al/Cr sandwich for source/drain contacts. Source and drain were patterned, a—Si:H islands were separated, and vias to gate electrodes were opened by etching.

a—Si:H TFTs with the OSG gate dielectric in the top-gate co-planar geometry were also fabricated. These TFTs are not described further in the present disclosure, but they were functional as well, and may enable introduction of the top-gate geometry to industrial use.

The TFTs were evaluated for their I_{DS}-V_{DS} output characteristics, their I_{DS}-V_{GS} transfer characteristics, and their gate-bias-stress stability, with an HP4155A parameter analyzer. For the output characteristics, the source drain voltage was swept from 0 V to 20 V, and the gate voltage was swept from 10 to 22 V in steps of 2 V. For transfer characteristics, the gate voltage was swept from 20 to −10 V at a drain-source bias of 10 V and 0.1 V. During gate-bias stressing the source and drain were grounded, and a positive voltage was applied to the gate for 600 s. Then the transfer characteristic was measured again by sweeping the gate voltage from 20 to −10 V. The gate-bias voltages was varied from 5 V to 80 V, which means that electric field across the gate insulator was varied from 0.2 to 3.2 MV/cm. The shift in the threshold voltage was determined on the subthreshold slope of the transfer curves, at the drain-current value of 1×10⁻¹ A.

### 4. Results

### TFT 1

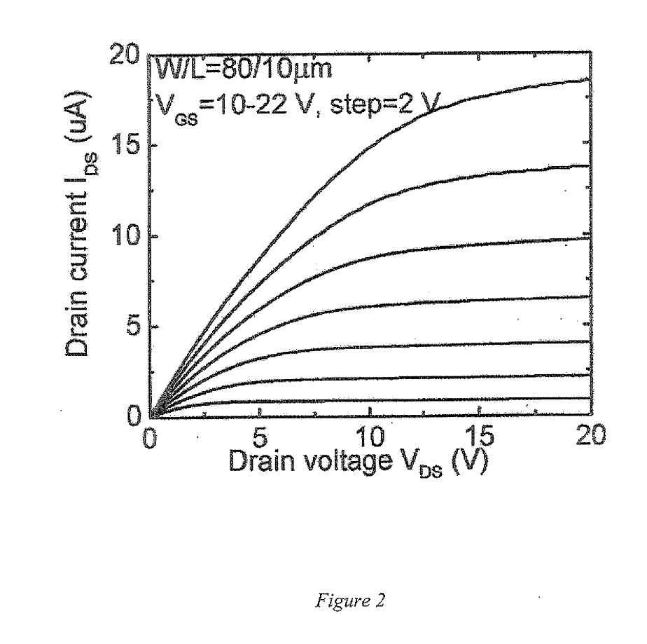

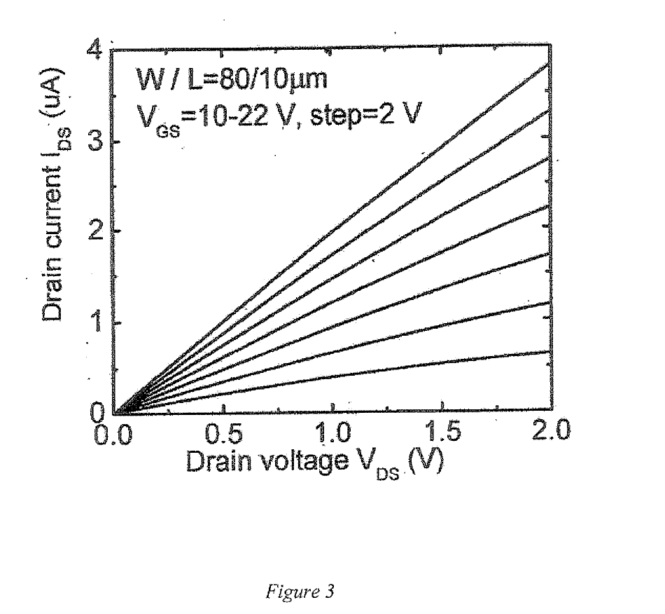

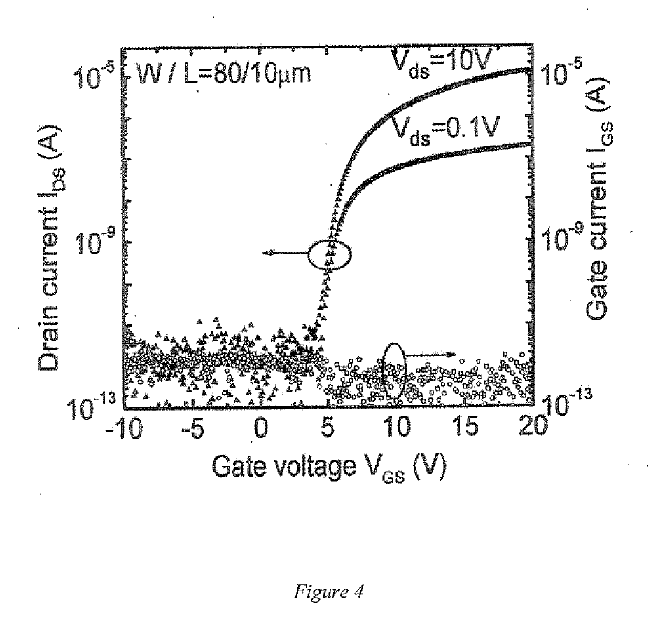

FIG. 2 shows the I_{DS}-V_{DS} characteristics of TFT 1 with channel width and channel length of 80 μm and 10 μm, respectively. The linear region is enlarged and shown in FIG. 3. The transfer characteristics are shown in FIG. 4. An electron field-effect mobility of 1.11 cm²/V·s in the linear region is extracted from the slope of drain current versus gate voltage, the ratio of gate width W to gate length L, the gate capacitance C and the drain-source bias voltage of 0.1 V. The saturation mobility of 1.12 cm²/V·s is derived from the slope of square root of the drain current versus gate voltage, W/L ratio, and gate capacitance. The threshold voltage is ˜5 V, the on/off current ratio is over 10⁷, and the subthreshold slope is 500 mV/decade.

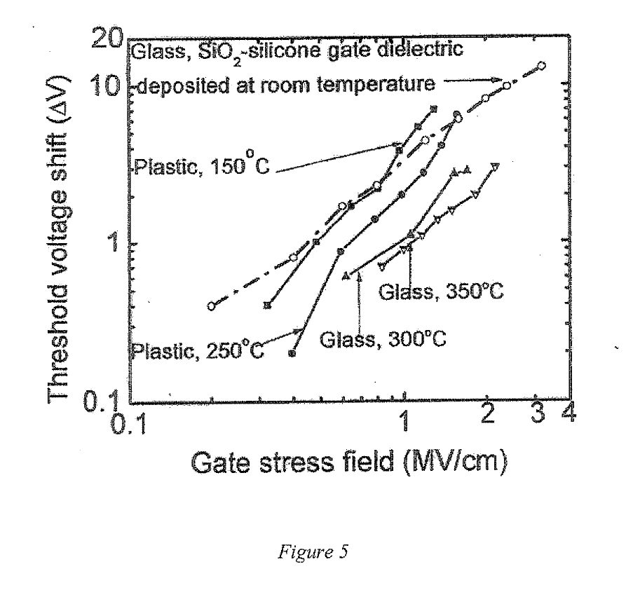

The threshold-voltage shifts after gate-bias stressing are shown in FIG. 5, together with literature data of other TFTs with SiNₓ-gate dielectrics deposited over a range of substrate temperatures. (K. Long, et al., IEEE Electron Device Lett., 27:111-113, 2006; K. H. Cherenack, et al., IEEE Electron Device Lett., 28:1004-1006, 2007; F. R. Libsch and J. Kanicki, Appl. Phys. Lett., 62:1286-1288, 1993).

The literature teaches that the threshold-voltage stability of a—Si:H TFTs using SiNₓ gate dielectrics improves as the process temperature is raised. For TFT 1, although the SiO₂-silicone hybrid gate dielectric was deposited at nominal room temperature, the stability of TFT 1 was comparable to that of other TFTs using conventional SiNₓ for the gate dielectric fabricated at 150° C. on plastic. Moreover, at higher gate-bias stressing, the stability of TFT 1 exceeds that of the TFT using conventional SiNₓ for the gate dielectric fabricated at 150° C. In more recently obtained data, TFTs made according to the present invention had threshold-voltage stabilities that exceed even TFTs using SiNₓ-gate dielectrics fabricated at 350° C. (Data not shown here, but see Lin Han et al., “A New Gate Dielectric for Highly Stable Amorphous-Silicon Thin-Film Transistors With ˜1.5-cm²/V·s Electron Field-Effect Mobility,” IEEE Electron Device Lett. 30:5, pp. 502-504 (May 2009), which is incorporated by reference herein.)

### TFT 2

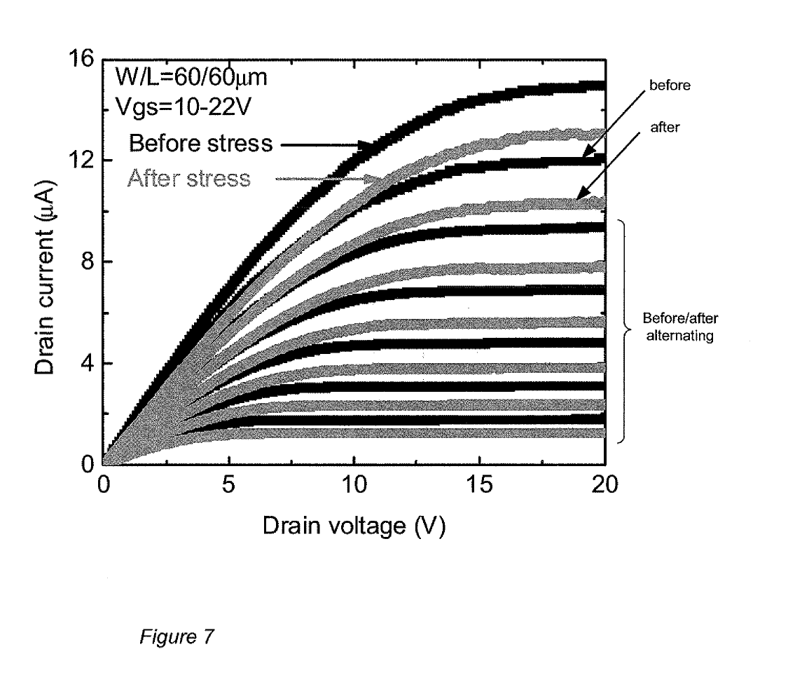

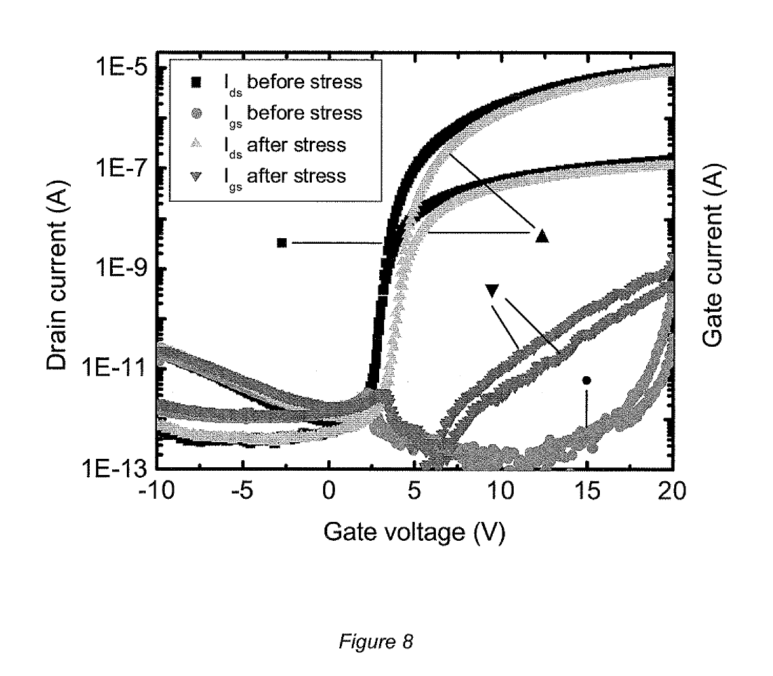

FIG. 7 shows the I_{DS}-V_{DS} characteristics of TFT 2 with channel width of 60 μm and channel length of 60 μm. The characteristics are shown before and after bias stressing. The transfer characteristics and gate leakage current before and after bias stressing are shown in FIG. 8. This TFT had a threshold voltage of 2.9 V; and electron field-effect mobility of 2.37 cm²/V·s in the linear regime and 2.29 cm²/V·s in the saturated regime.

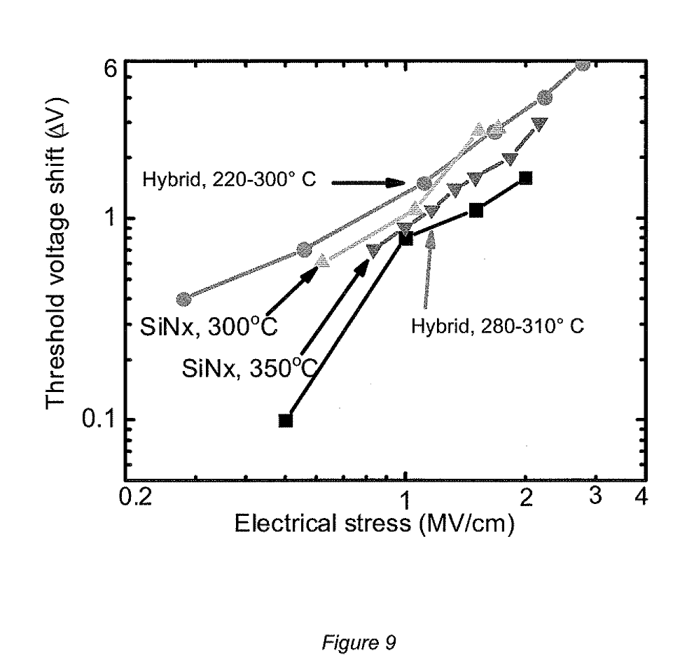

The threshold-voltage shifts after gate-bias stressing of TFT 2 are shown in FIG. 9, again together with literature data of other TFTs with SiNₓ-gate dielectrics deposited over a range of substrate temperatures. The data suggest that the threshold-voltage shift of TFT 2 was about half that of a conventional a—Si:H TFT with the SiNₓ-gate dielectric deposited at the same or similar temperatures as the hybrid dielectric of TFT 2. A comparison of some of the basic electrical properties of the hybrid SiO₂-silicone dielectric and SiNₓ dielectrics is shown in Table 1 below. Note that the hybrid SiO₂-silicone dielectric has a higher capacitance than the SiNₓ dielectric material.

TABLE 1
Properties of SiO₂-silicone hybrid dielectric and of
conventional SiNₓ gate dielectric for a-Si: H TFTs.

| | Hybrid | SiNₓ |
|---|---|---|
| Insulator thickness (nm) | 100 | 300 |
| Relative dielectric constant | 4.0 | 7.6 |
| Specific capacitance (F/cm²) | 3.5 × 10⁻⁸ | 2.2 × 10⁻⁸ |
| Subthreshold slope (mV/decade) | 270 | 500 |
| Dielectric breakdown field E_{bd} (MV/cm) | ~8 | ~5 |

### TFT 3

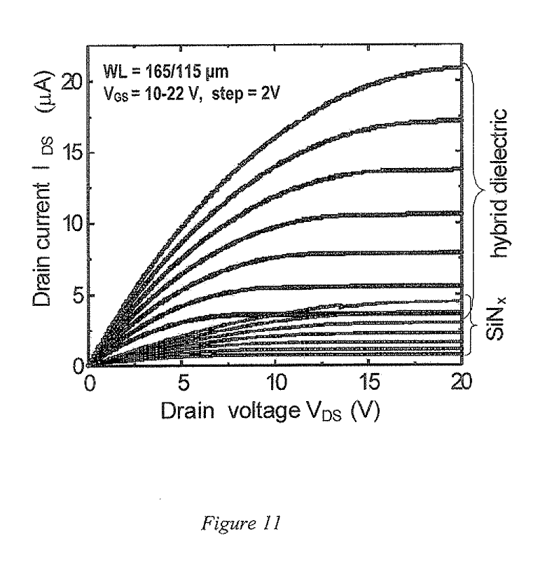

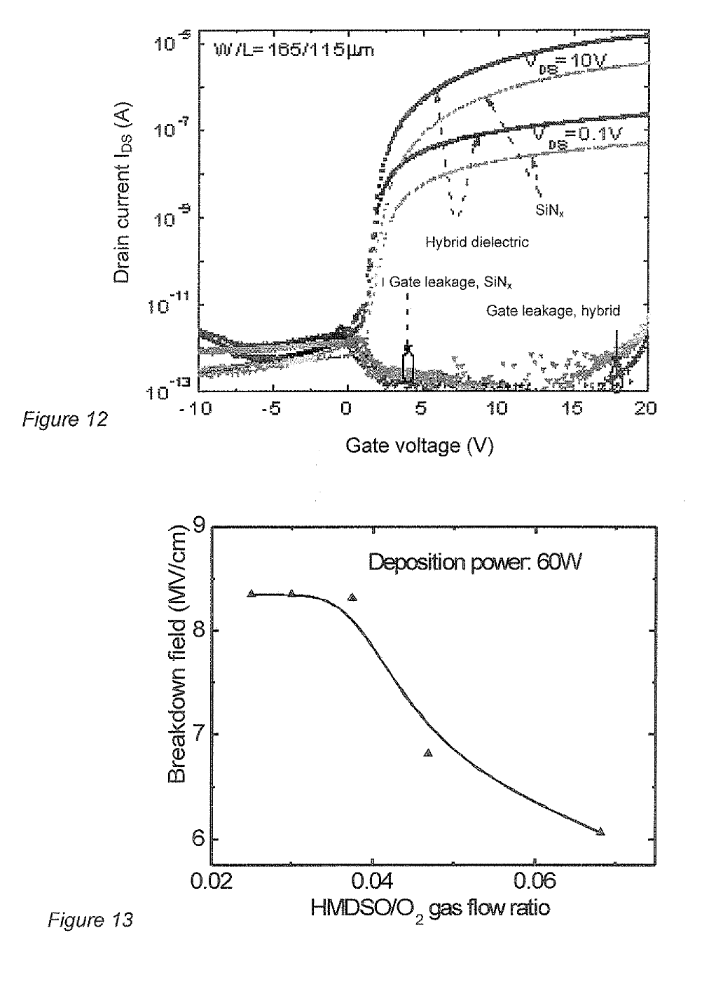

FIGS. 11 and 12 compare the characteristics of TFT 3 with a hybrid dielectric to the characteristics of a conventional TFT manufactured with SiNₓ as the gate dielectric. Dimensions and measurement conditions are identical except for the gate dielectric and back channel layers. Output (I_{DS}-V_{DS}) characteristics plotted in FIG. 11 show that the “hybrid” TFT produces ˜4× the current of the “SiNₓ” TFT. The DC transfer (log₁₀[I_{DS}-V_{GS}]) characteristics of FIG. 12 show that OFF and gate leakage currents of ˜1 pA are similar for both TFTs, a higher ON current and ON/OFF ratio for the “hybrid” TFT, and a subthreshold slope of 270 mV/dec for the “hybrid” vs. 500 mV/dec for the “SiNₓ” TFT. The least-squares fits of FIG. 4 to the saturated (V_{DS}=10V) and linear regimes (V_{DS}=0.1V) of the “hybrid” TFT yield μ_{n,sat}=2.0 cm²/V·s and μ_{n,lin}=2.1 cm²/V·s, and V_{T}=2.0 and 2.5 V, respectively.

### TFT 4

These TFTs adhered well to the foil substrate (see below), and were found to have an electron field-effect mobility of 1.2 cm²/V·s, subthreshold slope of 300 mV/decade, ON/OFF ratio of 10⁷, and leakage current of 10⁻¹² A.

### Flexibility of TFTs Built on Hybrid OSG-Passivated Polyimide

The resilient SiO₂-silicone hybrid material was used to passivate a 50 μm-thick polyimide substrate foil prior to TFT fabrication (see section 2.2 above.) Substrates were passivated with approximately 300-nm thick layers of the hybrid material on both faces of the substrate or only on the TFT side of the substrate. Adhesion of the hybrid passivation layers to the polyimide substrate may optionally be improved, by depositing approximately 10 nm thick SiNₓ subbing layers prior to the deposition of the hybrid layers. Individual TFTs built upon passivated polyimide were bent to known radii for one minute and then flattened for measurement of transfer characteristics. The axis of bending was perpendicular to the source-drain current path. This process was repeated until the TFT failed electrically. TFTs made with the hybrid dielectric demonstrated similar flexibility conventional TFTs made with SiNₓ, when strained in compression, but exhibited significantly increased flexibility when strained in tension.

Under bending to compressive strain, all TFTs tested delaminated from the substrate for compressive strains greater than 2%, regardless of whether the substrate was passivated on both faces or on the TFT side only. Conventional a—Si:H/SiNₓ TFTs have been previously found to delaminate at a similar compressive strain. Under bending to tensile strain, TFTs made with the new hybrid material on substrates passivated on both faces did not exhibit significant changes in transfer characteristics under strains of up to ˜0.8% and remained functional under strains of up to 1.6%. Conventional a—Si:H/SiNₓ TFTs on substrates passivated on both faces have been found to exhibit changes in transfer characteristics at ˜0.4% tensile strain and remain functional for strains of up to 0.5%, a value over 3 times less than that for TFTs made with the new hybrid material.

On substrates passivated on the TFT side only, hybrid dielectric TFTs did not exhibit significant changes in transfer characteristics for tensile strains of up to ˜2.5%. The performance of conventional a—Si:H/SiNₓ TFTs on substrates passivated on the TFT side only deteriorates when strained in tensile to ˜0.5%, a value 5 times less than that for TFTs made with the new hybrid material. These results suggest that TFTs made with the new dielectric material have the potential to enhance the flexibility and durability of large area electronics, such as displays and sensors.

The electron field-effect mobilities achieved in the results above are surprisingly high considering that other a—Si:H TFTs using SiNₓ gate dielectrics have an electron field-effect mobility of about 1 cm²/V·s. (See, for example, D. Striakhilev et al., J. Display Technol., vol. 2, p. 364 (2006)). One analysis reported that the effective electron field-effect mobility for a high performance a—Si:H TFT reaches 1.2 cm²/V·s in the linear region, 1.5 cm²/V·s in the saturation region, and have an intrinsic mobility of 1.6 cm²/V·s (see J. Kanicki & S. Martin, “Thin-Film Transistors,” C. Kagan and P. Andry, eds., p. 108, Marcel Dekker (2003)). Therefore, the electron field-effect mobilities obtained in the above described a-Si:H TFTs are surprisingly high.

The high electron field-effect mobilities in the results above suggest that the interface between the gate insulator layer and the a—Si:H channel has an unusually low density of traps. In certain embodiments, a transistor of the present invention has an effective electron field-effect mobility in the linear region of greater than 1.5 cm²/V·s, and in some cases, greater than 2.0 cm²/V·s. In certain embodiments, a transistor of the present invention has an on/off current ratio of greater than 1×10⁵, and in some cases, greater than 1×10⁶, and in some cases, greater than 1×10⁷. In certain embodiments, a transistor of the present invention has a threshold voltage (Vₜₕ) of less than 4.0 V, and in some cases, less than 2.0 V. In certain embodiments, a transistor of the present invention has a subthreshold slope of less than 500 mV/dec, and in some cases, less than 300 mV/dec. The subthreshold slope characterizes the sharpness of the field-effect onset and is given by S=dV_{GS}/d(log I_{DS}), where V_{GS} is the voltage at the gate, and I_{DS} is the current between the drain and source in the region where the behavior is linear (i.e., V_{GS}<Vₜₕ). Such performance characteristics may be difficult to achieve with SiNₓ-gate dielectric layers having a thickness of less than 300 nm.

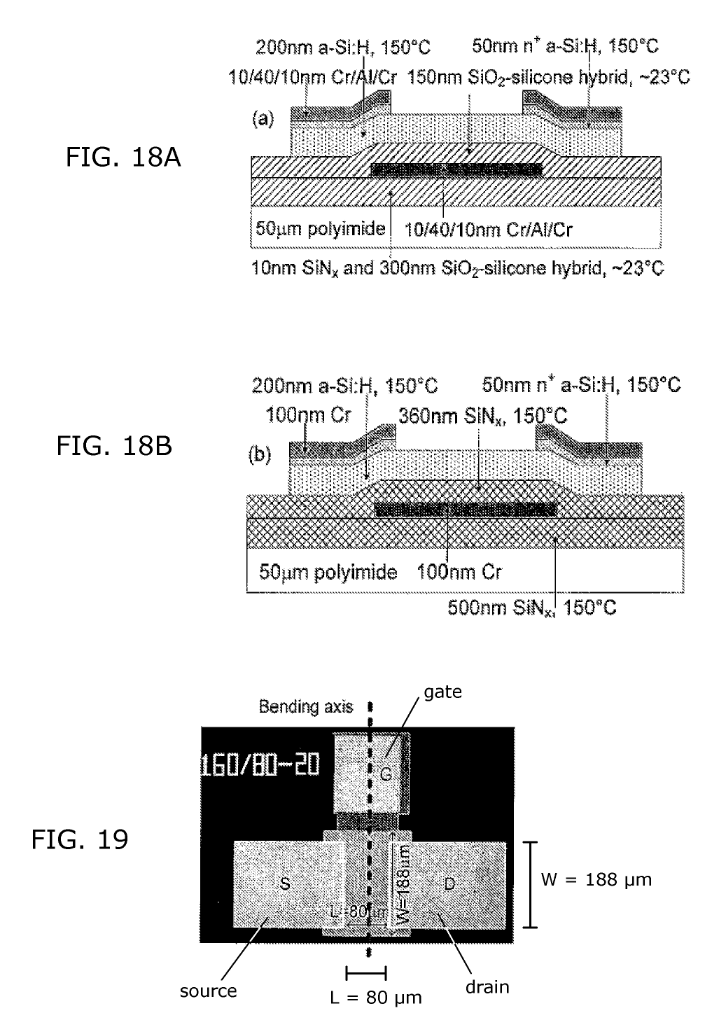

Further testing of the flexibility of TFTs (thin film transistors, field-effect type) made using the homogenous, hybrid silicon oxide/polymer (silica-silicone) material as the gate insulator material is described as follows. As shown in FIGS. 18A and 18B, TFTs with amorphous Si:H as the semiconductor material were fabricated in a range of widths and lengths in a conventional inverted staggered, back-channel cut geometry on passivated 50 μm thick Kapton E polyimide foils. FIG. 18B shows a conventional TFT that was made using a standard 150° C. plasma-enhanced chemical vapor deposition (PE-CVD) fabrication process with SiNₓ as the gate insulation material. FIG. 18A shows an experimental TFT made using a hybrid silica-silicone material as the gate insulating material. Where possible, the hybrid silica-silicone TFTs were fabricated using the same steps as the conventional SiN_{X} TFTs. One difference was that the deposition of the hybrid gate insulator layer required transfer to a different PE-CVD chamber. After deposition of the hybrid gate insulator layer, the TFT-in-process was transferred back to the conventional PE-CVD chamber for depositing the amorphous Si:H channel layer. Due to laboratory equipment constraints, the hybrid material gate insulator was exposed to air during this transfer. Other differences include the following: (i) the hybrid silica-silicone material was also used for substrate passivation with a 10 nm SiNₓ layer for improving adhesion; (ii) the hybrid gate insulator layer was thinner in the experimental TFT than the corresponding SiNₓ layer in the conventional TFT; and (iii) the experimental TFT used Cr/Al/Cr composite gate electrode and source/drain contacts that were thinner compared to the pure Cr gate electrode and source/drain contacts used in the conventional TFT.

FIG. 19 shows a micrograph of a representative hybrid material TFT, with W being the width of the amorphous Si:H island and L being the channel length (source to drain distance). The TFTs were subject to flexibility testing around cylinders of successively smaller radii R by bending around the axis shown in FIG. 19 (see dotted line). The testing sequence was as follows: electrical measurement, then bending for 1 minute, then flattening, and then electrical measurement again. The strain (ε) induced in the TFT by the bending was approximated by treating the TFT-on-substrate composite as a homogenous sheet of thickness h, with ε=h/2·R. See Suo et al., Applied Physics Letters, vol. 74:8, pp. 1177-1179 (1999), which is incorporated by reference herein. This strain relationship indicates that flexibility can be increased by reducing h, which is a design parameter. The level of strain at which the TFT experiences electrical failure is denoted as ε_{critical}. There are various ways to increase the flexibility of the TFT (i.e., the strain tolerance or ε_{critical}), including modifying the material composition of the TFT, reducing the thickness d of the TFT (with ε_{critical} being proportional to 1/\sqrt{d}), and improving the adhesion of the TFT to the substrate (which affects ε_{critical} in compression).

A set of 20 hybrid material TFTs having a channel width of 65 μm and a channel length (source to drain distance) of 15 μm were fabricated for tensile strain testing (bending with the TFT facing outward). Of these, 3 of the TFTs were discarded because of failure during manipulation, 17 withstood bending to R=0.75 mm (ε=3.3%), and of these, 2 of the TFTs withstood further bending to R=0.5 mm (ε=5%).

Another set of 20 hybrid material TFTs having a channel width of 20 μm and a channel length (source to drain distance) of 10 μm were fabricated for compressive strain testing (bending with the TFT facing inward). Of these, 17 of the TFTs withstood bending to R=1.25 mm (ε=2%), and of these, 5 withstood further bending to R=1.0 mm (ε=2.5%). During outward (tensile) bending, cracks appeared first in the source/drain contact and gate contact pads, and then in the channel, where cracks developed preferentially at the edge of the source/drain contacts. During inward (compression) bending, the TFTs peeled off first at the source/drain contacts and then in the channel.

As explained above, TFTs of the present invention can remain functional after tensile bending to a strain level (maximum tensile ε_{critical}) of 5%. This is about 10 times higher than the maximum tensile ε_{critical} of comparable SiNₓ TFTs, which is about 0.5%. See Gleskova et al., Applied Physics Letters, vol. 75, p. 3011 (1999). Electrical failure in tensile strain is believed to result from cracks in the channel. As explained above, TFTs of the present invention can remain functional after compressive bending to a strain level (maximum compressive ε_{critical}) of 2.5%, which is improved over the 2% that is observed for comparable conventional SiNₓ TFTs. Electrical failure in compressive strain is believed to result from buckling that is coupled with delamination. Also, for comparative purposes, the tensile ε_{critical of} an approximately 1 μm thick amorphous Si:H layer was reported to be about 2%. See Guha et al., Appl. Phys. Lett. 47, 947 (1985).

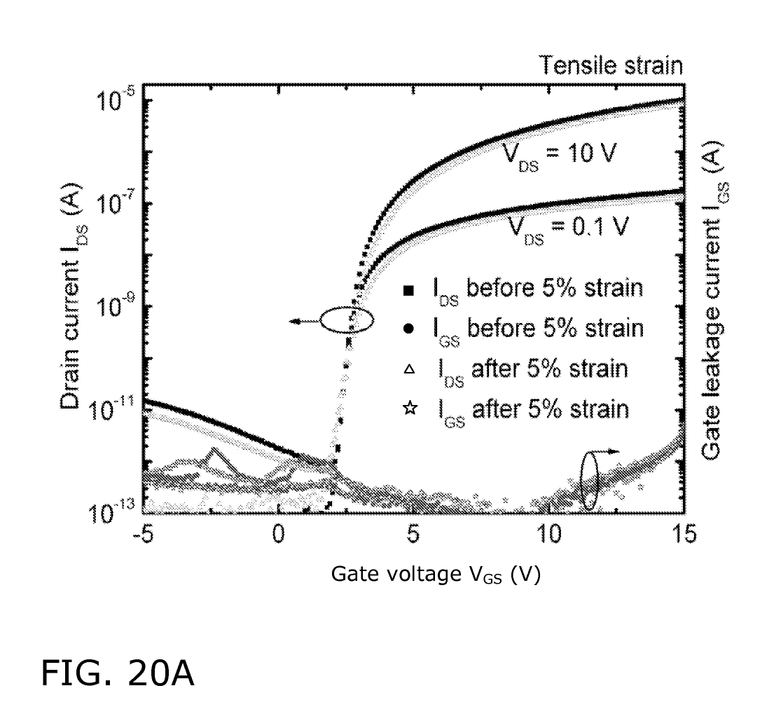

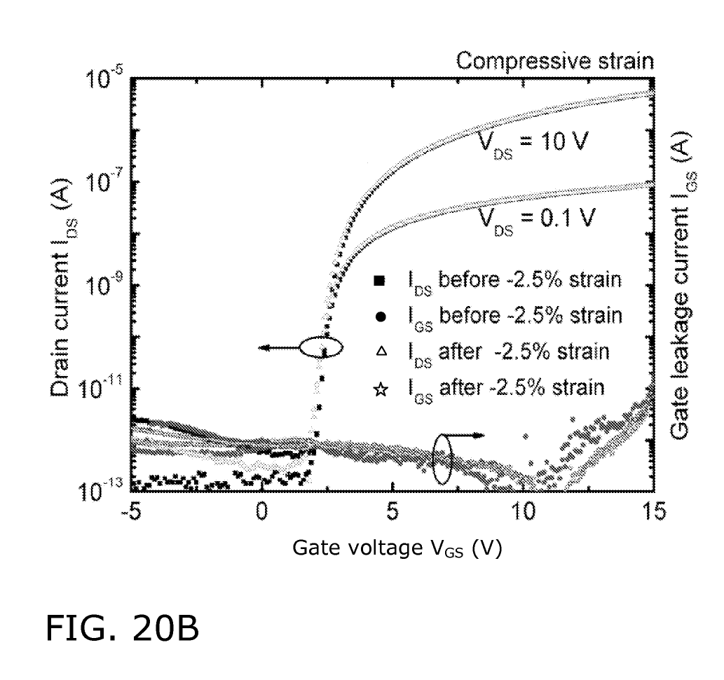

FIG. 20 shows representative plots of the transfer characteristics obtained for the hybrid material TFTs before and after bending. The TFTs were evaluated after re-flattening after each bending step. Results from the tensile strain testing are given in FIG. 20A, which shows a plot of drain current (I_{DS}, in amps, on the left vertical axis) vs. gate voltage (V_{GS}, in volts) and gate-source leakage current (I_{GS}, in amps, on the right vertical axis) vs. gate voltage (V_{GS}) before and after bending to a maximum tensile strain of +5%. This hybrid material TFT had an intrinsic electron mobility (μ) of 1.6 cm²/V·s in the linear region. The darker-shaded line (▪) plots the drain current prior to bending and the lighter-shaded line (Δ) plots the drain current after bending. As seen here, there was no significant change in the electrical characteristics of the TFT after tensile bending.

Results from the compressive strain testing are given in FIG. 20B, which shows a plot of drain current (I_{DS}, in amps, on the left vertical axis in base-10 logarithmic scale) vs. gate voltage (V_{GS}, in volts) and gate-source leakage current (I_{GS}, in amps, on the right vertical axis) vs. gate voltage (V_{GS}, in volts) before and after bending to a maximum compressive strain of −2.5%. This hybrid material TFT had an intrinsic electron mobility (μ) of 1.6 cm²/V·s in the linear region. The darker-shaded line (▪) plots the drain current prior to bending and the lighter-shaded line (Δ) plots the drain current after bending. As seen here, there was no significant change in the electrical characteristics of the TFT after compressive bending.

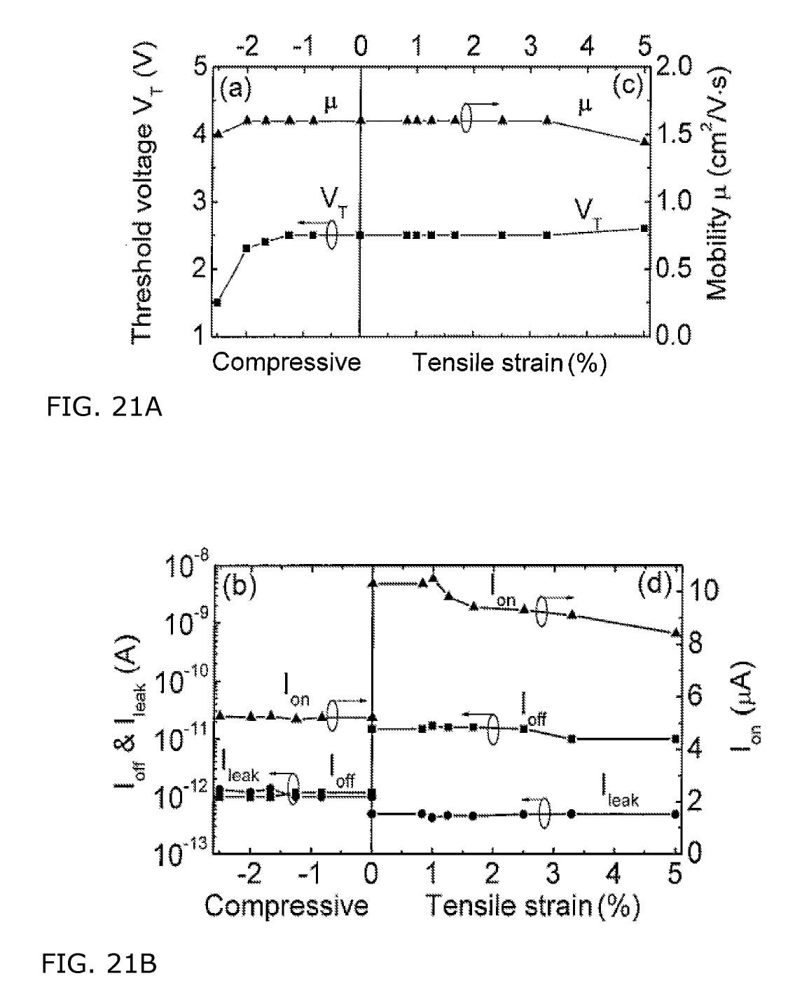

Based on these measurements of the TFTs, the following transistor characteristics were determined: threshold voltage (V_{T}) and electron mobility (μ) in the linear regime, ON current (Iₒₙ) at a gate voltage of 15 V, OFF current (I_{off}) at a gate voltage of −5 V, and gate leakage current (Iₗₑₐₖ)at a gate voltage of −5 V. FIG. 21 shows a plot of these electrical characteristics according to the amount of strain induced in the TFT. In both FIGS. 21A and 21B, the vertical line over 0 is prior to any bending. Panels (a) and (b) on the left side of the plot shows each point of compressive strain that was tested. From the center 0, the points correspond to radius R=3.0, 2.0, 1.5, 1.25, and 1.0 mm. Panels (c) and (d) on the right side of the plot shows each point of tensile strain that was tested. From the center 0, the points correspond to radius R=3.0, 2.5, 2.0, 1.5, 1.0, 0.75, and 0.5 mm.

In FIG. 21A, the lower plot (▪) corresponds to the threshold voltage as read on the left vertical axis. The upper plot (▴) corresponds to electron mobility as read on the right vertical axis. In FIG. 21B, the (▴) plot corresponds to ON current (Iₒₙ) as read on the right vertical axis, the (▪) plot corresponds to the OFF current (I_{off}) as read on the left vertical axis, and the () plot corresponds to the gate leakage current (Iₗₑₐₖ) read on the left vertical axis.

Thus, these experiments demonstrate that the TFTs of the present invention can remain functional despite being strained to a tensile strain of up to 5%, a compressive strain of up to 2.5%, or both. Thus, TFTs of the present invention can remain functional after bending to a tensile strain of more than 0.5%; and in some cases, more than 2%; and in some cases, up to 5%. In some cases, TFTs of the present invention can remain functional after bending to a compressive strain of more than 2%; and in some cases, up to 2.5%. Furthermore, by extrapolation of the experimental results and/or routine improvement in the processing and fabrication capabilities (e.g., vacuum processing), TFTs of the present invention may be capable of remaining functional after being subjected to even greater amounts of strain. Thus, in some cases, TFTs of the present invention can be strained and remain functional after being subjected to a tensile strain of greater than 5%, a compressive strain of greater than 2.5%, or both. As used herein, the term “functional” when referring to the TFT means that the TFT maintains an ON/OFF current ratio of at least 10⁵ and an electron mobility of at least 0.5 cm²/Vs (linear region) after bending and then re-flattening.

With this significant improvement in TFT flexibility, other components of the device, such as the substrate or encapsulation layer, may become the limiting factor in overall flexibility. In fact, in one of the strain tests, a crease formed in the polyimide substrate after bending outward to a radius of 0.5 mm; but the TFT remained intact, indicating that the TFT was more flexible than the substrate. As such, the present invention may lead to the use of more flexible substrates. In general, a substrate can be made more flexible by making it thinner. Thus, in some cases, the substrate for the TFT may have a thickness of less than 50 μm; and in some cases, less than 25 μm; and in some cases, as thin as 10 μm.

In some cases, the substrate may be made more flexible by using alternate materials for making the substrate, including materials other than polyimide. For example, such alternate materials may be more flexible and/or mechanically stronger than polyimide. In some cases, the substrate may be made using a composite material, such as a polymer composite material. Composite materials are materials made from two or more constituent materials having significantly different physical or chemical properties that remain separate and distinct within the finished structure at a macroscopic or microscopic scale. An example of a composite material is a fiber-reinforced, polymer composite material containing embedded fibers for mechanical reinforcement.

As the term is used herein, if an item A is more “flexible” than item B, then item B will become permanently deformed or permanently dysfunctional before item A as they are both subjected to the same bending force. For a TFT, an example of permanent deformation is delamination of the TFT off the substrate or cracking of the TFT channel. For a substrate, an example of permanent deformation is the formation of a crease in the substrate when the substrate is bent.

Whereas all-organic TFTs may have substantial flexibility, the present invention may be particularly useful for improving the flexibility of TFTs that use inorganic semiconductor materials such as inorganic silicon, cadmium selenium, and metal oxides (such as zinc oxide). Examples of inorganic silicon materials include amorphous silicon (including hydrogenated amorphous silicon) and crystalline silicon (including polycrystalline, nanocrystalline, or microcrystalline silicon).

The present invention can also be embodied as a display screen having a hybrid material TFT described herein. The display screen may be an organic light-emitting display screen having multiple organic light-emitting elements that are driven by the TFTs. In some cases, the display screen may further include an encapsulation layer over the TFT and the organic light-emitting elements to serve as a permeation barrier against environmental contaminants (e.g., moisture and oxygen). In some cases, the encapsulation layer may be made with the hybrid silica-silicone material of the present invention. Examples of how such an encapsulation layer may be used with organic light-emitting devices are described in International Publication No. WO 2010/011390 (Mandlik et al.), which is incorporated by reference herein. With the TFT being sandwiched between the substrate and the encapsulation layer, the TFT may be held in a strain-neutral plane, which can suppress strain-induced changes in transistor characteristics. See Sekitani et al., Applied Physics Letters, vol. 87:173502 (2005).

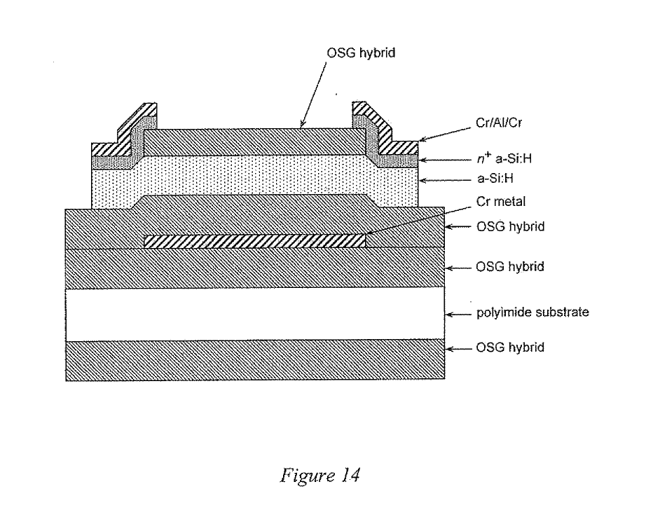

In some cases, the display screen may further include a protective barrier layer disposed over the encapsulation layer (e.g., as a top layer), with the protective barrier layer having sufficient hardness and/or thickness to provide protection from mechanical damage. Examples of such barrier coatings are described in International Publication No. WO 2010/011390 (Mandlik et al.), which is incorporated by reference herein. Being an insulating dielectric material, the hybrid silica-silicone material may also be used in other components of the display screen, such as a passivation layer for the substrate (see, e.g., FIG. 14 above) or between the metal interconnections for the TFTs. For example, a hybrid material encapsulation layer may penetrate into spaces between the metal interconnections so that the metal interconnections are insulated from each other.

Because of the flexibility of the hybrid material TFT, the display screen may be rolled into a cylindrical shape for storage and unfurled for viewing. As such, the display screen may be used in an electronic device having a pull-out display screen that is rolled onto a spindle. The display screen may be stored in the rolled configuration and then unfurled for viewing. The display screen can be used for any of various types of electronic devices, including handheld devices, mobile phones, smart phones, personal digital assistants (PDAs), digital cameras or camcorders, tablet computers, portable laptop or notebook computers, flat panel displays, computer monitors, televisions, billboards, lights for interior or exterior illumination and/or signaling, heads up displays, fully transparent displays, flexible displays, laser printers, viewfinders, micro-displays, vehicles, a large area wall, theater or stadium screen, or a sign. In some cases, the electronic device may be a portable electronic device (e.g., handhelds, cell phones, smart phones, personal digital assistants (PDAs), digital cameras and camcorders, tablet computers, portable laptop or notebook computers, etc.).

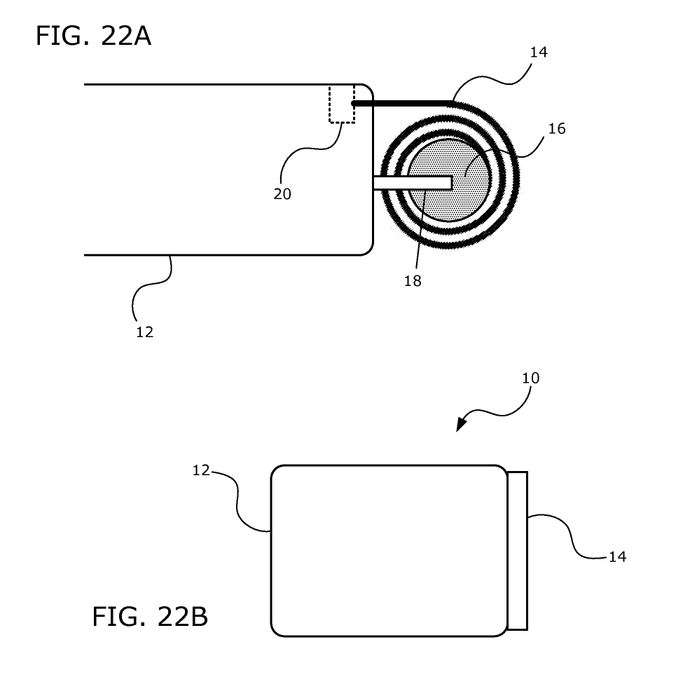

FIGS. 22A and 22B show an example of a handheld electronic device 10 of the present invention. FIG. 22A shows a partial, side view of the electronic device 10; and FIG. 22B shows a top view of the electronic device 10. The electronic device 10 has a main body 12 and a flexible display screen 14, which is rolled onto a spindle 16 that is connected to main body 12 by an extendable frame 18. Display screen 14 is electrically connected to main body 12 via a connector 20.

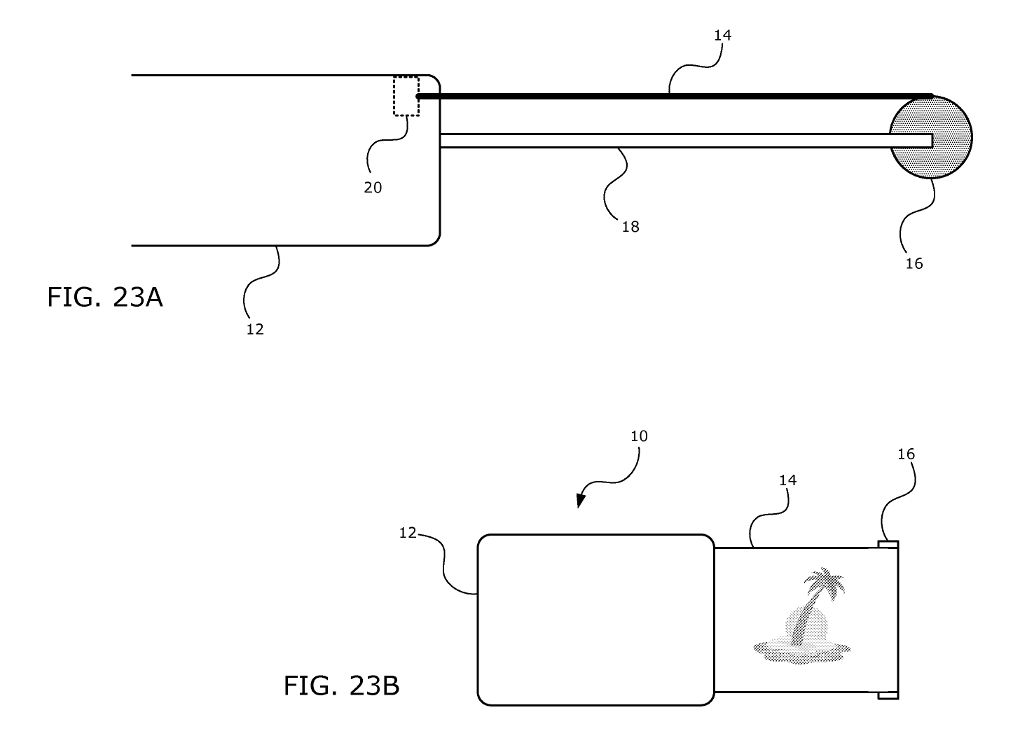

As demonstrated in the experiments, the TFTs of the present invention are capable of being rolled to a radius as small as 0.5 mm with outward bending (tension) or as small as 1 mm with inward bending (compression). Thus, the spindle may have a diameter of less than 20 mm; and in some cases, less than 15 mm; and in some cases, less than 10 mm; and in some cases, less than 5 mm; and in some cases, as small as 1 mm. But other spindle diameters are also possible. As shown in FIGS. 23A and 23B, to view display screen 14, frame 18 is extended outward and display screen 14 unfurls off of spindle 16. When display screen 14 is no longer needed, frame 18 is retracted back into main body 12 to roll display screen 14 back onto spindle 16.

It is understood that the various embodiments described herein are by way of example only, and are not intended to limit the scope of the invention. For example, many of the materials and structures described herein may be substituted with other materials and structures without deviating from the spirit of the invention. It is understood that various theories as to why the invention works are not intended to be limiting. Each of the disclosed aspects and embodiments of the present invention may be considered individually or in combination with other aspects, embodiments, and variations of the invention. In addition, unless otherwise specified, the steps of the methods of the present invention are not confined to any particular order of performance.

We claim:

1. An electronic device comprising a field-effect transistor, the field-effect transistor comprising:
a semiconductor active layer comprising a semiconductor material;
a source electrode and a drain electrode;
a gate electrode; and
an insulating material disposed between the gate electrode and the semiconductor active layer, the insulating material consisting essentially of a hybrid silica-silicone material.

2. The device of claim 1, wherein the hybrid silica-silicone material comprises from 70% to 95% silicon dioxide and 30% to 5% siloxane polymer.

3. The device of claim 1, wherein the device is a display screen.

4. The device of claim 3, wherein the field-effect transistor is capable of remaining functional after being subjected to a compressive strain of up to 2%.

5. The device of claim 3, further comprising a substrate that is passivated on both sides, wherein the field-effect transistor is capable of remaining functional after being subjected to a tensile strain of up to 1.6%.

6. The device of claim 3, further comprising a substrate that is passivated only on the side facing the field-effect transistor, wherein the field-effect transistor is capable of remaining functional after being subjected to a tensile strain of up to 2.5%.

7. The device of claim 5, wherein the field-effect transistor is capable of remaining functional after being subjected to a tensile strain in the range of 0.5-1.6%.

8. The device of claim 6, wherein the field-effect transistor is capable of remaining functional after being subjected to a tensile strain in the range of 0.5-2.5%.

9. The device of claim 3, wherein the semiconductor material is amorphous silicon.

10. The device of claim 9, wherein the display screen is an organic light-emitting display screen.

11. An electronic device comprising:
an organic light-emitting display screen comprising a substrate and a field-effect transistor, wherein the field-effect transistor comprises:
(a) a semiconductor active layer comprising a semiconductor material;
(b) a source electrode and a drain electrode;
(c) a gate electrode; and
(d) an insulator layer disposed between the gate electrode and the semiconductor active layer, the insulator layer consisting essentially of a hybrid silica-silicone material.

12. The electronic device of claim 11, further comprising a spindle, wherein the display screen is rolled on the spindle.

13. The electronic device of claim 12, wherein the diameter of the spindle is less than 15 mm.

14. The electronic device of claim 11, wherein the display screen is rolled into a cylindrical shape.

15. The electronic device of claim 11, wherein the semiconductor material is inorganic silicon.

16. The electronic device of claim 11, wherein the field-effect transistor is capable of remaining functional after being subjected to a tensile strain of up to 5%, a compressive strain of up to 2.5%, or both.

17. The electronic device of claim 11, wherein the field-effect transistor is more flexible than the substrate.

18. The electronic device of claim 11, further comprising an encapsulation layer over the field-effect transistor.

19. The electronic device of claim 18, wherein the hybrid silica-silicone material of the insulator layer is a first hybrid silica-silicone material, and wherein the encapsulation layer consists essentially of a second hybrid silica-silicone material that may or may not be the same as the first hybrid silica-silicone material.

20. The electronic device of claim 19, further comprising a passivation layer between the substrate and the field-effect transistor, wherein the passivation consists essentially of a third hybrid silica-silicone material that may or may not be the same as the first or second hybrid silica-silicone materials.

21. The electronic device of claim 19, wherein the organic light-emitting display screen comprises multiple field-effect transistors and multiple metal interconnections that connect with the field-effect transistors, and wherein the second hybrid silica-silicone material of the encapsulation layer electrically insulates the metal interconnections from each other.

22. The electronic device of claim 19, further comprising a protective barrier layer over the encapsulation layer.

23. The electronic device of claim 22, wherein the field-effect transistor is held in a substantially neutral plane between the substrate and the protective barrier layer.
